(19) United States
(12) Patent Application Publication
(10) Pub. No.: US 2025/0383376 A1
(43) Pub. Date: Dec. 18, 2025

(54) METHOD AND APPARATUS FOR ELECTRONIC MUTUAL INDUCTOR, AND ELECTRONIC MUTUAL INDUCTOR

(71) Applicant: Siemens Aktiengesellschaft, München (DE)

(72) Inventors: Shu Yao Zhao, Nanjing (CN); Federico Canas, Falkensee (DE); Qi Cao, Nanjing (CN); Qian Wang, Chongqing (CN); Xuan Sun, Nanjing (CN)

(21) Appl. No.: 18/878,236

(22) PCT Filed: Jun. 20, 2023
(86) PCT No.: PCT/EP2023/066613

§ 371 Date: Dec. 23, 2024

(30) Foreign Application Priority Data
Jun. 23, 2022 (CN) 202210719041.0

(51) Int. Cl. G01R 15/18; G01R 19/00

(52) U.S. Cl. CPC G01R 15/181; G01R 19/0092

(57) ABSTRACT

A method and apparatus for electronic mutual inductance, and an electronic mutual inductor. The method includes: determining a coefficient of mutual induction of a Rogowski coil of each phase of the electronic mutual inductor and determining crosstalk induction of each phase to the Rogowski coils of other phases; based on the corresponding coefficient of mutual induction and crosstalk induction of each phase, acquiring a compensation coefficient for an output voltage of the secondary side of that phase. The compensation coefficient is used to compensate for a real-time output voltage value of the secondary side of the electronic mutual inductor to acquire a compensation voltage value that corresponds to an actual current value of the primary-side device. This allows the actual current value of the primary-side device to be accurately acquired.

### TECHNICAL FIELD

The present invention relates to the field of power systems, in particular to a method and apparatus for an electronic mutual inductor, and an electronic mutual inductor.

### BACKGROUND ART

With the rapid development of electronic technology, small-signal acquisition technology has been applied increasingly more widely in power systems, including electronic mutual inductors. Electronic mutual inductors have a number of advantages including small size, light weight, and ease of digitization, and are widely used in digitized transformer substations.

An electronic mutual inductor based on Rogowski coils is a hollow inductance coil formed by winding wires on a non-magnetic framework with a circular cross-section. The theoretical bases for measuring a current with a Rogowski coil is Faraday's law of electromagnetic induction and Ampere's circuital law, wherein, when the measured current passes through the center of the Rogowski coil along the axis, a magnetic field that changes accordingly is generated within the volume enclosed by the annular winding. The secondary side of such an electronic mutual inductor outputs a voltage signal, which is directly proportional to the derivative of the current on the primary side and needs to be integrated to restore the current signal.

The current on the primary side of an electronic mutual inductor based on a Rogowski coil can be up to thousands of amperes, and due to the limitation on the mechanical size of the electronic mutual inductor, the physical distance between the three-phase currents therein is not large. Due to electromagnetic induction, the magnetic field generated by the current in each phase will be coupled to the Rogowski coils of the other two phases and generate a corresponding induced voltage, so the final output voltage of each phase of the electronic mutual inductor will be superimposed with the voltage induced by the other phase currents in the Rogowski coils of that phase, which is an effect known as interphase crosstalk, and the magnitude of generated crosstalk induction is related to the uniformity of the Rogowski coil winding and the installation positions of wires in each phase. Therefore, the output voltage of the secondary side of each phase cannot accurately reflect the primary-side current of the phase corresponding thereto, and consequently, a result obtained based on the electronic mutual inductor is inaccurate.

### SUMMARY OF THE INVENTION

The invention is, in particular, defined by the enclosed claims.

In view of what has been mentioned above, the present invention proposes a method for an electronic mutual inductor, wherein the electronic mutual inductor is provided with three phases each having a Rogowski coil, and the electronic mutual inductor is used to convert a current of a primary-side device into a secondary-side voltage, the method comprising:
determining a coefficient of mutual induction of the Rogowski coil of each phase of the electronic mutual inductor and determining crosstalk induction of each phase to Rogowski coils of other phases;
based on the corresponding coefficient of mutual induction and the crosstalk induction of each phase, acquiring a compensation coefficient for an output voltage of the secondary side of that phase, the compensation coefficient being used to compensate for a real-time output voltage value of the secondary side of the electronic mutual inductor to acquire a compensation voltage value that corresponds to an actual current value of the primary-side device.

According to the method described above, optionally, determining the coefficient of mutual induction of the Rogowski coil of each phase and determining the crosstalk induction of each phase to the Rogowski coils of the other phases comprises:
when a quantitative current is applied, in turn, to the primary side of one phase, acquiring a first voltage output from the secondary side of each phase while keeping the primary side of the other two phases currentless;
based on each of the first voltages, determining a coefficient of mutual induction of the Rogowski coil of each phase, and the crosstalk induction of the Rogowski coil of each phase to the other two phases.

According to the method described above, optionally, determining the coefficient of mutual induction of the Rogowski coil of each phase and the crosstalk induction of each phase to the Rogowski coil of each of said reference phases according to the following formula comprises:
three phases of the electronic mutual inductor are phase A, phase B, and phase C, respectively, wherein, when the quantitative current is applied to phase A, and phase B and phase C are kept currentless,

$$\{ \begin{matrix}{M}_{A} = \frac{{V}_{A \_ sec}}{2 π f \cdot {I}_{A \_ pri}} \\ {M}_{AtoB} = \frac{{V}_{B \_ sec}}{2 π f \cdot {I}_{A \_ pri}} \\ {M}_{AtoC} = \frac{{V}_{C \_ sec}}{2 π f \cdot {I}_{A \_ pri}}\end{matrix}$$

wherein M_{A} represents the coefficient of mutual induction of the Rogowski coil of phase A, M_{AtoB} represents the crosstalk induction of the Rogowski coil of phase A to phase B, M_{AtoC} represents the crosstalk induction of the Rogowski coil of phase A to phase C, I_{A_pri} represents a quantitative current of phase A, f represents the frequency of the quantitative current, V_{A_sec} represents a first voltage on the secondary side of phase A, V_{B_sec} represents a first voltage on the secondary side of phase B, and V_{C_sec} represents a first voltage on the secondary side of phase C;
under a condition of applying a quantitative current to phase B and keeping phase A and phase C currentless,

$$\{ \begin{matrix}{M}_{BtoA} = \frac{{V}_{A \_ sec}}{2 π f \cdot {I}_{{B}_{pri}}} \\ {M}_{B} = \frac{{V}_{B \_ sec}}{2 π f \cdot {I}_{{B}_{pri}}} \\ {M}_{BtoC} = \frac{{V}_{C \_ sec}}{2 π f \cdot {I}_{{B}_{pri}}}\end{matrix}$$

wherein M_{B} represents the coefficient of mutual induction of the Rogowski coil of phase B, M_{BtoA} represents the crosstalk induction of phase B to the Rogowski coil of phase A, M_{BtoC} represents the crosstalk induction of phase B to the Rogowski coil of phase C, and I_{B_pri} represents a quantitative current of phase B;

under a condition of applying a quantitative current to phase C and keeping phases A and B currentless,

$$\{ \begin{matrix}{M}_{CtoA} = \frac{{V}_{A \_ sec}}{2 π f \cdot {I}_{C \_ pri}} \\ {M}_{CtoB} = \frac{{V}_{B \_ sec}}{2 π f \cdot {I}_{C \_ pri}} \\ {M}_{C} = \frac{{V}_{C \_ sec}}{2 π f \cdot {I}_{C \_ pri}}\end{matrix}$$

wherein M_{C} represents the coefficient of mutual induction of the Rogowski coil of phase C, M_{CtoA} represents the crosstalk induction of phase C to the Rogowski coil of phase A, M_{CtoB} represents the crosstalk induction of phase C to the Rogowski coil of phase B, and I_{C_pri} represents a quantitative current of phase C.

According to the method described above, optionally, based on the corresponding coefficient of mutual induction and the crosstalk induction of each phase, acquiring a compensation coefficient for an output voltage of the secondary side of that phase comprises:
under the normal operating state of the electronic mutual inductor, measuring a second voltage output on the secondary side of each phase, the second voltage comprising an induced voltage generated by the Rogowski coil induction of the phase and a crosstalk voltage generated by the crosstalk of the other two phases to the phase;
determining the compensation coefficient of the output voltage on the secondary side of each phase based on the second voltage, the coefficient of mutual induction, and the crosstalk induction of each phase.

According to the method described above, optionally, the compensation coefficient matrix D is determined according to the following formula:

$$D = [ \begin{matrix}{Fct}_{A} & {Fct}_{BtoA} & {Fct}_{CtoA} \\ {Fct}_{AtoB} & {Fct}_{B} & {Fct}_{CtoB} \\ {Fct}_{AtoC} & {Fct}_{BtoC} & {Ftc}_{C}\end{matrix} ]$$

$$\{ \begin{matrix}{Fct}_{A} = \frac{{M}_{A} \cdot ( {M}_{B} \cdot {M}_{C} - {M}_{BtoC} \cdot {M}_{CtoB} )}{N} \\ {Fct}_{BtoA} = \frac{{M}_{A} \cdot ( {M}_{BtoC} \cdot {M}_{CtoA} - {M}_{BtoA} \cdot {M}_{C} )}{N} \\ {Fct}_{CtoA} = \frac{{M}_{A} \cdot ( {M}_{BtoA} \cdot {M}_{CtoB} - {M}_{B} \cdot {M}_{CtoA} )}{N} \\ {Fct}_{AtoB} = \frac{{M}_{B} \cdot ( {M}_{AtoC} \cdot {M}_{CtoB} - {M}_{AtoB} \cdot {M}_{C} )}{N} \\ {Fct}_{B} = \frac{{M}_{B} \cdot ( {M}_{A} \cdot {M}_{C} - {M}_{AtoC} \cdot {M}_{CtoA} )}{N} \\ {Fct}_{CtoB} = \frac{{M}_{B} \cdot ( {M}_{AtoB} \cdot {M}_{CtoA} - {M}_{A} \cdot {M}_{CtoB} )}{N} \\ {Fct}_{AtoC} = \frac{{M}_{C} \cdot ( {M}_{AtoB} \cdot {M}_{BtoC} - {M}_{AtoC} \cdot {M}_{B} )}{N} \\ {Fct}_{BtoC} = \frac{{M}_{C} \cdot ( {M}_{AtoC} \cdot {M}_{BtoA} - {M}_{A} \cdot {M}_{BtoC} )}{N} \\ {Fct}_{C} = \frac{{M}_{C} \cdot ( {M}_{A} \cdot {M}_{B} - {M}_{AtoB} \cdot {M}_{BtoA} )}{N}\end{matrix}$$

$$and N = {M}_{A} \cdot {M}_{B} \cdot {M}_{C} + {M}_{AtoC} \cdot {M}_{BtoA} \cdot {M}_{CtoB} + {M}_{CtoA} \cdot {M}_{AtoB} \cdot {M}_{BtoC} - {M}_{AtoC} \cdot {M}_{B} \cdot {M}_{CtoA} - {M}_{A} \cdot {M}_{BtoC} \cdot {M}_{CtoB} - {M}_{C} \cdot {M}_{AtoB} \cdot {M}_{BtoA} .$$

According to the method described above, optionally, the compensation coefficient is used to determine the compensation voltage value according to the following formula:

$$\{ \begin{matrix}{V}_{A \_ comp} = {Fct}_{A} \cdot {V}_{A \_ meas} + {Fct}_{BtoA} \cdot {V}_{B \_ meas} + {Fct}_{CtoA} \cdot {V}_{C \_ meas} \\ {V}_{B \_ comp} = {Fct}_{AtoB} \cdot {V}_{A \_ meas} + {Fct}_{B} \cdot {V}_{B \_ meas} + {Fct}_{CtoB} \cdot {V}_{C \_ meas} \\ {V}_{C \_ comp} = {Fct}_{AtoC} \cdot {V}_{A \_ meas} + {Fct}_{BtoC} \cdot {V}_{B \_ meas} + {Fct}_{C} \cdot {V}_{C \_ meas}\end{matrix}$$

in the formula, V_{A_comp} represents the compensation voltage value of phase A, V_{B_comp} represents the compensation voltage value of phase B, V_{C_comp} represents the compensation voltage value of phase C, V_{A_meas} represents a real-time output voltage value of the secondary sides of phase A, V_{B_meas} represents a real-time output voltage value of the secondary sides of phase B, and V_{C_meas} represents a real-time output voltage value of the secondary sides of phase C.

The present invention further provides a method for an electronic mutual inductor, wherein the electronic mutual inductor is provided with three phases each having a Rogowski coil, and the electronic mutual inductor is used to convert a current of the primary-side device into a secondary-side voltage, the method comprising:
based on the real-time current of each phase of the primary-side device, generating a real-time output voltage of the corresponding phase;
according to a predetermined compensation coefficient for each phase, compensating for the real-time output voltage on each phase to acquire the corresponding compensation voltage value of each phase, wherein the compensation coefficient is determined based on the coefficients of mutual induction of the Rogowski coils of each phase and the crosstalk induction of each phase to the Rogowski coils of the other phases; and
sending the compensation voltage value to a target device, the compensation voltage value corresponding to an actual current value of the primary-side device.

According to the method described above, optionally, the compensation coefficient matrix D is:

$$D = [ \begin{matrix}{Fct}_{A} & {Fct}_{BtoA} & {Fct}_{CtoA} \\ {Fct}_{AtoB} & {Fct}_{B} & {Fct}_{CtoB} \\ {Fct}_{AtoC} & {Fct}_{BtoC} & {Fct}_{C}\end{matrix} ]$$

$$\{ \begin{matrix}{Fct}_{A} = \frac{{M}_{A} \cdot ( {M}_{B} \cdot {M}_{C} - {M}_{BtoC} \cdot {M}_{CtoB} )}{N} \\ {Fct}_{BtoA} = \frac{{M}_{A} \cdot ( {M}_{BtoC} \cdot {M}_{CtoA} - {M}_{BtoA} \cdot {M}_{C} )}{N} \\ {Fct}_{CtoA} = \frac{{M}_{A} \cdot ( {M}_{BtoA} \cdot {M}_{CtoB} - {M}_{B} \cdot {M}_{CtoA} )}{N} \\ {Fct}_{AtoB} = \frac{{M}_{B} \cdot ( {M}_{AtoC} \cdot {M}_{CtoB} - {M}_{AtoB} \cdot {M}_{C} )}{N} \\ {Fct}_{B} = \frac{{M}_{B} \cdot ( {M}_{A} \cdot {M}_{C} - {M}_{AtoC} \cdot {M}_{CtoA} )}{N} \\ {Fct}_{CtoB} = \frac{{M}_{B} \cdot ( {M}_{AtoB} \cdot {M}_{CtoA} - {M}_{A} \cdot {M}_{CtoB} )}{N} \\ {Fct}_{AtoC} = \frac{{M}_{C} \cdot ( {M}_{AtoB} \cdot {M}_{BtoC} - {M}_{AtoC} \cdot {M}_{B} )}{N} \\ {Fct}_{BtoC} = \frac{{M}_{C} \cdot ( {M}_{AtoC} \cdot {M}_{BtoA} - {M}_{A} \cdot {M}_{BtoC} )}{N} \\ {Fct}_{C} = \frac{{M}_{C} \cdot ( {M}_{A} \cdot {M}_{B} - {M}_{AtoB} \cdot {M}_{BtoA} )}{N}\end{matrix}$$

$$and N = {M}_{A} \cdot {M}_{B} \cdot {M}_{C} + {M}_{AtoC} \cdot {M}_{BtoA} \cdot {M}_{CtoB} + {M}_{CtoA} \cdot {M}_{AtoB} \cdot {M}_{BtoC} - {M}_{AtoC} \cdot {M}_{B} \cdot {M}_{CtoA} - {M}_{A} \cdot {M}_{BtoC} \cdot {M}_{CtoB} - {M}_{C} \cdot {M}_{AtoB} \cdot {M}_{BtoA} ;$$

wherein M_{A} represents the coefficient of mutual induction of the Rogowski coil of phase A, M_{AtoB} represents the crosstalk induction of the Rogowski coil of phase A to phase B, M_{AtoC} represents the crosstalk induction of the Rogowski coil of phase A to phase C, I_{A_pri} represents a quantitative current of phase A, f represents the frequency of the quantitative current, V_{A_sec} represents a first voltage on the secondary side of phase A, V_{B_sec} represents a first voltage on the secondary side of phase B, and V_{C_sec} represents a first voltage on the secondary side of phase C;
M_{B} represents the coefficient of mutual induction of the Rogowski coil of phase B, M_{BtoA} represents the crosstalk induction of phase B to the Rogowski coil of phase A, M_{BtoC} represents the crosstalk induction of phase B to the Rogowski coil of phase C, and I_{B_pri} represents a quantitative current of phase B;
M_{C} represents the coefficient of mutual induction of the Rogowski coil of phase C, M_{CtoA} represents the crosstalk induction of phase C to the Rogowski coil of phase A, M_{CtoB} represents the crosstalk induction of phase C to the Rogowski coil of phase B, and I_{C_pri} represents a quantitative current of phase C.

According to the method described above, optionally, the step of, according to a predetermined compensation coefficient for each phase, compensating for the real-time output voltage on each phase to acquire the corresponding compensation voltage value for each phase comprises:

$$\{ \begin{matrix}{V}_{A \_ comp} = {Fct}_{A} \cdot {V}_{A \_ meas} + {Fct}_{BtoA} \cdot {V}_{B \_ meas} + {Fct}_{CtoA} \cdot {V}_{C \_ meas} \\ {V}_{B \_ comp} = {Fct}_{AtoB} \cdot {V}_{A \_ meas} + {Fct}_{B} \cdot {V}_{B \_ meas} + {Fct}_{CtoB} \cdot {V}_{C \_ meas} \\ {V}_{C \_ comp} = {Fct}_{AtoC} \cdot {V}_{A \_ meas} + {Fct}_{BtoC} \cdot {V}_{B \_ meas} + {Fct}_{C} \cdot {V}_{C \_ meas}\end{matrix}$$

V_{A_comp} represents the compensation voltage value of phase A, V_{B_comp} represents the compensation voltage value of phase B, V_{C_comp} represents the compensation voltage value of phase C, V_{A_meas} represents a real-time output voltage value of the secondary sides of phase A, V_{B_meas} represents a real-time output voltage value of the secondary sides of phase B, and V_{C_meas} represents a real-time output voltage value of the secondary sides of phase C.

The present invention further provides an apparatus for an electronic mutual inductor, wherein the electronic mutual inductor is provided with three phases each having a Rogowski coil, the electronic mutual inductor is used to convert a current of a primary side device into a secondary side voltage, the electronic mutual inductor further comprising:
a first determining unit for determining the coefficients of mutual induction of each phase of the Rogowski coil of the electronic mutual inductor and determining the crosstalk induction of each phase to the Rogowski coils of the other phases;
a first acquisition unit, used to, based on the corresponding coefficient of mutual induction and crosstalk induction of each phase, acquire a compensation coefficient of the output voltage on the secondary side of that phase, wherein the compensation coefficient is used to compensate for the real-time output voltage value on the secondary side of the electronic mutual inductor to acquire a compensation voltage value, the compensation voltage value corresponding to an actual current value on the primary side.

According to the apparatus described above, optionally, the first determining unit is specifically used for:
the three phases of the electronic mutual inductor are phase A, phase B, and phase C, respectively, wherein, when a quantitative current is applied to phase A, and phase B and phase C are kept currentless,

$$\{ \begin{matrix}{M}_{A} = \frac{{V}_{A \_ sec}}{2 π f \cdot {I}_{A \_ pri}} \\ {M}_{AtoB} = \frac{{V}_{B \_ sec}}{2 π f \cdot {I}_{A \_ pri}} \\ {M}_{AtoC} = \frac{{V}_{C \_ sec}}{2 π f \cdot {I}_{A \_ pri}}\end{matrix}$$

wherein M_{A} represents the coefficient of mutual induction of the Rogowski coil of phase A, M_{AtoB} represents the crosstalk induction of the Rogowski coil of phase A to phase B, M_{AtoC} represents the crosstalk induction of the Rogowski coil of phase A to phase C, I_{A_pri} represents a quantitative current of phase A, f represents the frequency of the quantitative current, V_{A_sec} represents a first voltage on the secondary side of phase A, V_{B_sec} represents a first voltage on the secondary side of phase B, and V_{C_sec} represents a first voltage on the secondary side of phase C;
under a condition of applying a quantitative current to phase B and keeping phase A and phase C currentless.

$$\{ \begin{matrix}{M}_{BtoA} = \frac{{V}_{A \_ sec}}{2 π f \cdot {I}_{{B}_{pri}}} \\ {M}_{B} = \frac{{V}_{B \_ sec}}{2 π f \cdot {I}_{{B}_{pri}}} \\ {M}_{BtoC} = \frac{{V}_{C \_ sec}}{2 π f \cdot {I}_{{B}_{pri}}}\end{matrix}$$

wherein M_{B} represents the coefficient of mutual induction of the Rogowski coil of phase B, M_{BtoA} represents the crosstalk induction of phase B to the Rogowski coil of phase A, M_{BtoC} represents the crosstalk induction of phase B to the Rogowski coil of phase C, and I_{B_pri} represents a quantitative current of phase B;
under a condition of applying a quantitative current to phase C and keeping phase A and phase B currentless,

$$\{ \begin{matrix}{M}_{CtoA} = \frac{{V}_{A \_ sec}}{2 π f \cdot {I}_{C \_ pri}} \\ {M}_{CtoB} = \frac{{V}_{B \_ sec}}{2 π f \cdot {I}_{C \_ pri}} \\ {M}_{C} = \frac{{V}_{C \_ sec}}{2 π f \cdot {I}_{C \_ pri}}\end{matrix}$$

wherein M_{C} represents the coefficient of mutual induction of the Rogowski coil of phase C, M_{CtoA} represents the crosstalk induction of phase C to the Rogowski coil of phase A, M_{CtoB} represents the crosstalk induction of phase C to the Rogowski coil of phase B, and I_{C_pri} represents a quantitative current of phase C.

According to the apparatus described above, optionally, the first acquisition unit is specifically used to:
determine a compensation coefficient matrix D according to the following formula:

$$D = [ \begin{matrix}{Fct}_{A} & {Fct}_{BtoA} & {Fct}_{CtoA} \\ {Fct}_{AtoB} & {Fct}_{B} & {Fct}_{CtoB} \\ {Fct}_{AtoC} & {Fct}_{BtoC} & {Fct}_{C}\end{matrix} ]$$

$$\{ \begin{matrix}{Fct}_{A} = \frac{{M}_{A} \cdot ( {M}_{B} \cdot {M}_{C} - {M}_{BtoC} \cdot {M}_{CtoB} )}{N} \\ {Fct}_{BtoA} = \frac{{M}_{A} \cdot ( {M}_{BtoC} \cdot {M}_{CtoA} - {M}_{BtoA} \cdot {M}_{C} )}{N} \\ {Fct}_{CtoA} = \frac{{M}_{A} \cdot ( {M}_{BtoA} \cdot {M}_{CtoB} - {M}_{B} \cdot {M}_{CtoA} )}{N} \\ {Fct}_{AtoB} = \frac{{M}_{B} \cdot ( {M}_{AtoC} \cdot {M}_{CtoB} - {M}_{AtoB} \cdot {M}_{C} )}{N} \\ {Fct}_{B} = \frac{{M}_{B} \cdot ( {M}_{A} \cdot {M}_{C} - {M}_{AtoC} \cdot {M}_{CtoA} )}{N} \\ {Fct}_{CtoB} = \frac{{M}_{B} \cdot ( {M}_{AtoB} \cdot {M}_{CtoA} - {M}_{A} \cdot {M}_{CtoB} )}{N} \\ {Fct}_{AtoC} = \frac{{M}_{C} \cdot ( {M}_{AtoB} \cdot {M}_{BtoC} - {M}_{AtoC} \cdot {M}_{B} )}{N} \\ {Fct}_{BtoC} = \frac{{M}_{C} \cdot ( {M}_{AtoC} \cdot {M}_{BtoA} - {M}_{A} \cdot {M}_{BtoC} )}{N} \\ {Fct}_{C} = \frac{{M}_{C} \cdot ( {M}_{A} \cdot {M}_{B} - {M}_{AtoB} \cdot {M}_{BtoA} )}{N}\end{matrix}$$

$$and N = {M}_{A} \cdot {M}_{B} \cdot {M}_{C} + {M}_{AtoC} \cdot {M}_{BtoA} \cdot {M}_{CtoB} + {M}_{CtoA} \cdot {M}_{AtoB} \cdot {M}_{BtoC} - {M}_{AtoC} \cdot {M}_{B} \cdot {M}_{CtoA} - {M}_{A} \cdot {M}_{BtoC} \cdot {M}_{CtoB} - {M}_{C} \cdot {M}_{AtoB} \cdot {M}_{BtoA} .$$

The present invention further provides an electronic mutual inductor, which is provided with three phases each having a Rogowski coil and is used to convert a current of a primary-side device into a secondary-side voltage, the electronic mutual inductor comprising:
a generating unit, used to, based on a real-time current of each phase of the primary-side device, generate a real-time output voltage of the corresponding phase;

The electronic mutual inductor further comprises:
a compensation unit, used to compensate for the real-time output voltage on each phase based on a predetermined compensation coefficient of each phase, and to acquire a compensation voltage value corresponding to each phase, the compensation coefficient being determined based on a coefficient of mutual induction of the Rogowski coil of each phase and crosstalk induction of the Rogowski coil of each phase to other phases;
a sending unit, used to send the compensation voltage value to a target device, the compensation voltage value corresponding to an actual current value of the primary-side device.

According to the electronic mutual inductor described above, optionally, the compensation coefficient matrix D is:

$$D = [ \begin{matrix}{Fct}_{A} & {Fct}_{BtoA} & {Fct}_{CtoA} \\ {Fct}_{AtoB} & {Fct}_{B} & {Fct}_{CtoB} \\ {Fct}_{AtoC} & {Fct}_{BtoC} & {Fct}_{C}\end{matrix} ]$$

$$\{ \begin{matrix}{Fct}_{A} = \frac{{M}_{A} \cdot ( {M}_{B} \cdot {M}_{C} - {M}_{BtoC} \cdot {M}_{CtoB} )}{N} \\ {Fct}_{BtoA} = \frac{{M}_{A} \cdot ( {M}_{BtoC} \cdot {M}_{CtoA} - {M}_{BtoA} \cdot {M}_{C} )}{N} \\ {Fct}_{CtoA} = \frac{{M}_{A} \cdot ( {M}_{BtoA} \cdot {M}_{CtoB} - {M}_{B} \cdot {M}_{CtoA} )}{N} \\ {Fct}_{AtoB} = \frac{{M}_{B} \cdot ( {M}_{AtoC} \cdot {M}_{CtoB} - {M}_{AtoB} \cdot {M}_{C} )}{N} \\ {Fct}_{B} = \frac{{M}_{B} \cdot ( {M}_{A} \cdot {M}_{C} - {M}_{AtoC} \cdot {M}_{CtoA} )}{N} \\ {Fct}_{CtoB} = \frac{{M}_{B} \cdot ( {M}_{AtoB} \cdot {M}_{CtoA} - {M}_{A} \cdot {M}_{CtoB} )}{N} \\ {Fct}_{AtoC} = \frac{{M}_{C} \cdot ( {M}_{AtoB} \cdot {M}_{BtoC} - {M}_{AtoC} \cdot {M}_{B} )}{N} \\ {Fct}_{BtoC} = \frac{{M}_{C} \cdot ( {M}_{AtoC} \cdot {M}_{BtoA} - {M}_{A} \cdot {M}_{BtoC} )}{N} \\ {Fct}_{C} = \frac{{M}_{C} \cdot ( {M}_{A} \cdot {M}_{B} - {M}_{AtoB} \cdot {M}_{BtoA} )}{N}\end{matrix}$$

$$and N = {M}_{A} \cdot {M}_{B} \cdot {M}_{C} + {M}_{AtoC} \cdot {M}_{BtoA} \cdot {M}_{CtoB} + {M}_{CtoA} \cdot {M}_{AtoB} \cdot {M}_{BtoC} - {M}_{AtoC} \cdot {M}_{B} \cdot {M}_{CtoA} - {M}_{A} \cdot {M}_{BtoC} \cdot {M}_{CtoB} - {M}_{C} \cdot {M}_{AtoB} \cdot {M}_{BtoA} ;$$

wherein M_{A} represents the coefficient of mutual induction of the Rogowski coil of phase A, M_{AtoB} represents the crosstalk induction of the Rogowski coil of phase A to phase B, M_{AtoC} represents the crosstalk induction of the Rogowski coil of phase A to phase C, I_{A_pri} represents a quantitative current of phase A, f represents the frequency of the quantitative current, V_{A_sec} represents a first voltage on the secondary side of phase A, V_{B_sec} represents a first voltage on the secondary side of phase B, and V_{C_sec} represents a first voltage on the secondary side of phase C;
M_{B} represents the coefficient of mutual induction of the Rogowski coil of phase B, M_{BtoA} represents the crosstalk induction of phase B to the Rogowski coil of phase A, M_{BtoC} represents the crosstalk induction of phase B to the Rogowski coil of phase C, and I_{B_pri} represents a quantitative current of phase B;
M_{C} represents the coefficient of mutual induction of the Rogowski coil of phase C, M_{CtoA} represents the crosstalk induction of phase C to the Rogowski coil of phase A, M_{CtoB} represents the crosstalk induction of phase C to the Rogowski coil of phase B, and I_{C_pri} represents a quantitative current of phase C.

According to the electronic mutual inductor described above, optionally, the compensation unit may be specifically used to:
compensate for a real-time output voltage of each phase by using the following formula:

$$\{ \begin{matrix}{V}_{A \_ comp} = {Fct}_{A} \cdot {V}_{A \_ meas} + {Fct}_{BtoA} \cdot {V}_{B \_ meas} + {Fct}_{CtoA} \cdot {V}_{C \_ meas} \\ {V}_{B \_ comp} = {Fct}_{AtoB} \cdot {V}_{A \_ meas} + {Fct}_{B} \cdot {V}_{B \_ meas} + {Fct}_{CtoB} \cdot {V}_{C \_ meas} \\ {V}_{C \_ comp} = {Fct}_{AtoC} \cdot {V}_{A \_ meas} + {Fct}_{BtoC} \cdot {V}_{B \_ meas} + {Fct}_{C} \cdot {V}_{C \_ meas}\end{matrix}$$

V_{A_comp} represents the compensation voltage value of phase A, V_{B_comp} represents the compensation voltage value of phase B, V_{C_comp} represents the compensation voltage value of phase C, V_{A_meas} represents a real-time output voltage value of the secondary sides of phase A, V_{B_meas} represents a real-time output voltage value of the secondary sides of phase B, and V_{C_meas} represents a real-time output voltage value of the secondary sides of phase C.

The present invention further provides an apparatus for an electronic mutual inductor, wherein the electronic mutual inductor is provided with three phases each having a Rogowski coil, and the electronic mutual inductor is used to convert a current of a primary side device into a secondary side voltage, the apparatus comprising:
at least one memory for storing an instruction;
at least one processor for executing the method for an electronic mutual inductor as described above according to an instruction stored in the memory.

The present invention further provides an electronic mutual inductor, which is provided with three phases each having a Rogowski coil, and is used to convert a current of a primary-side device into a secondary-side voltage, the apparatus comprising:
at least one memory for storing an instruction;
at least one processor for executing the method for an electronic mutual inductor as described above according to an instruction stored in the memory.

It is understood that the apparatus and/or mutual inductor can be implemented to carry out the methods as disclosed above or below with respect to the embodiments.

It is clear from the above-described solution that the corresponding compensation coefficient is determinable in advance based on the coefficient of mutual induction and crosstalk induction of the secondary side, and then the electronic mutual inductor can compensate for the real-time output voltage value of the secondary side by the compensation coefficient, wherein the obtained compensation voltage value corresponds to an actual current value of the primary-side device, providing a method that is highly universal and delivers high real-time performance.

### BRIEF DESCRIPTION OF THE DRAWINGS

The preferred embodiments of the present invention will be described in detail hereinafter with reference to the accompanying drawings, to make the above mentioned and other features and advantages of the present invention more apparent to those of ordinary skill in the art, in which:

FIG. 1 is a flowchart of a method for an electronic mutual inductor according to an embodiment of the present invention.

FIG. 2 is a flowchart of a method for an electronic mutual inductor according to another embodiment of the present invention.

FIG. 3 is a flowchart of a method for an electronic mutual inductor according to yet another embodiment of the present invention.

FIG. 4 is a structural schematic diagram of an apparatus for an electronic mutual inductor according to an embodiment of the present invention.

FIG. 5 is a structural schematic diagram of an apparatus for an electronic mutual inductor according to another embodiment of the present invention.

### SPECIFIC EMBODIMENTS

In order to make clearer the purposes, technical solutions, and advantages of the present invention, the present invention will be further described below in conjunction with embodiments.

The present invention provides a method for an electronic mutual inductor, the electronic mutual inductor comprising three phases: phase A, phase B, and phase C, and it is possible to, according to actual needs, determine which phases of the electronic mutual inductor are phase A, phase B, and phase C, respectively. Each phase has a Rogowski coil. An alternating current in the primary-side wire can generate a magnetic field, which in turn generates an induced voltage in the Rogowski coil in that phase, that is, an output voltage. In the present invention, by compensating for the output secondary side voltage, it is possible to acquire an accurate secondary-side voltage, thereby acquiring an accurate primary-side current.

### Embodiment 1

This embodiment provides a method for an electronic mutual inductor, which is executed mainly by an apparatus for an electronic mutual inductor, and the apparatus may be a desktop computer or personal digital assistant, or an electronic device connected to the electronic mutual inductor, which will not be further described herein. The electronic mutual inductor is provided with three phases each having a Rogowski coil. The electronic mutual inductor is used to convert a current of a primary-side device into a secondary-side voltage.

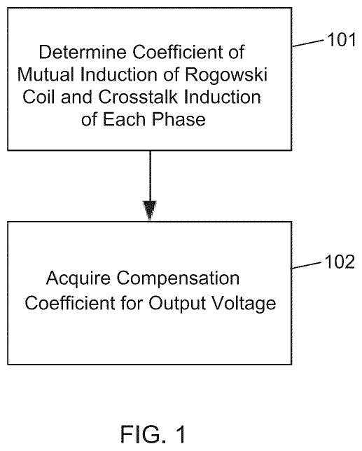

Refer to FIG. 1, which is a flowchart of a method for an electronic mutual inductor according to this embodiment. The method used for an electronic mutual inductor comprises:

Step 101: Determine the coefficient of mutual induction of the Rogowski coil of each phase of the electronic mutual inductor and determine the crosstalk induction of each phase to the Rogowski coils of the other phases.

An alternating current in the primary-side device generates a magnetic field, and the interaction between the magnetic field and the Rogowski coil generates an induced voltage within the coil, the induced voltage being proportional to the rate of change of the current. The ratio of the induced voltage to the rate of change of current in a Rogowski coil is known as induction. The coefficient of mutual induction refers to the induction between a primary-side current and the Rogowski coil of the local phase. The crosstalk induction refers to the induction between a primary-side current and the Rogowski coils of the other phases. The primary-side current refers to a current of the primary-side device.

Without following any sequences, the coefficient of mutual induction and crosstalk induction may be determined simultaneously or sequentially, depending on actual needs.

Step 102, based on the corresponding coefficient of mutual induction and the crosstalk induction of each phase, acquire a compensation coefficient for an output voltage of the secondary side of that phase, the compensation coefficient being used to compensate for a real-time output voltage value of the secondary sides of the electronic mutual inductor to acquire a compensation voltage value that corresponds to an actual current value of the primary-side device.

The compensation coefficient is determinable based on the output secondary-side voltage when there is interphase crosstalk in each phase and the output secondary-side voltage when there is no interphase crosstalk. An output voltage of an electronic mutual inductor based on the Rogowski coil is always a differential voltage.

When there is interphase crosstalk, the output secondary-side voltage comprises the voltage generated by current induction on one side of the phase and the voltage generated by the currents of the other two phases due to interphase crosstalk. The voltage generated by the current induction on the primary side of the phase is the output voltage on the secondary side when there is no interphase crosstalk, which can accurately reflect the current value of the primary side of the phase.

The output secondary-side voltage when there is interphase crosstalk and the output secondary-side voltage when there is interphase crosstalk may be directly measured by experiments to determine the corresponding compensation coefficient. Determined by the structure of an electronic mutual inductor itself, the compensation coefficient is constant, which remains unchanged when the primary-side current changes.

The compensation voltage value is represented corresponding to an actual current value on the primary side of the phase, wherein the compensation voltage value may be used to acquire an actual current value on the primary side of the phase, and it may also be understood that the compensation voltage value is proportional to an actual current value on the primary side. After the compensation coefficient of each phase of the electronic mutual inductor is confirmed, the compensation coefficient may be input into the electronic mutual inductor, and thus, the electronic mutual inductor can compensate for the real-time output voltage value of the secondary side, thereby acquiring the output secondary-side voltage when it is not affected by interphase interference. The output voltage is input into the secondary-side device, and then the actual current value on the primary side is determined based on the output voltage on the secondary side when it is not affected by interphase crosstalk.

The real-time output voltage may be acquired by the electronic mutual inductor.

According to this embodiment, the corresponding compensation coefficient may be determined in advance based on the coefficient of mutual induction and crosstalk induction of the secondary side, and then the electronic mutual inductor can compensate for the real-time output voltage value of the secondary side by the compensation coefficient, wherein the acquired compensation voltage value corresponds to the actual current value of the primary-side device, providing a method that is highly universal and delivers high real-time performance.

### Embodiment 2

This embodiment provides a method for an electronic mutual inductor to further explain the method of the aforementioned embodiment.

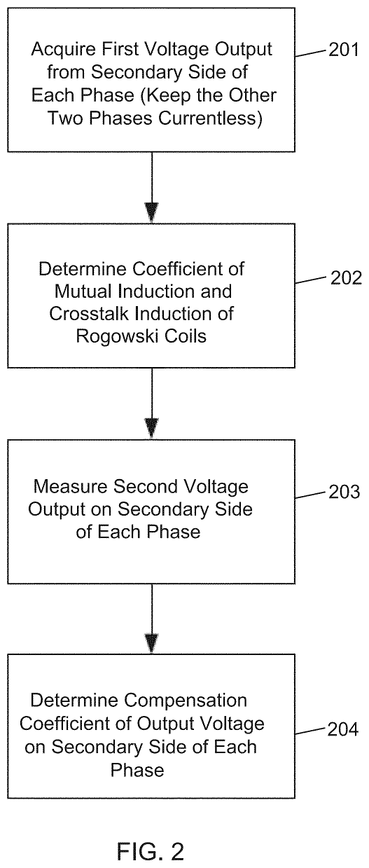

Refer to FIG. 2, which is a flowchart of a method for an electronic mutual inductor according to this embodiment. The method comprises:

Step 201: When a quantitative current is applied, in turn, to the primary sides of one phase, acquire a first voltage output from the secondary side of each phase while keeping the primary sides of the other two phases currentless,

An electronic mutual inductor has three phases. In turn, one phase is taken as the target phase and the other phases as the reference phases. Subsequently, corresponding actions will be performed for each target phase. A target phase is a phase that applies a quantitative current, and a reference phase is a phase that is kept currentless.

The frequency of the quantitative current may be set according to actual needs, wherein, for example, it may be the same as the frequency of the power system, namely, 50 Hz. The quantitative current is an alternating current with a definite frequency and an effective value.

As an example, the formula for the output voltage of a Rogowski coil is

$$u ( t ) = M \cdot \frac{di ( t )}{dt} ,$$

wherein u(t) represents the output voltage, i(t) represents the current corresponding to time t, which may be acquired by measurement, and M represents the coefficient of mutual induction of the Rogowski coil. Assuming the current i(t)=I·sin (2πf·t+φ) is set, then u(t)=2πf·M·I·sin (2πf·t+φ+90°). In the formula, I represents the peak value of the current, f represents the frequency of the current, and φ represents the angle of the current. In other words, V_{sec}=2πf·M·Iₚᵣᵢ, wherein Iₚᵣᵢ represents the quantitative current of the phase, and V_{sec} represents the output voltage of the phase. Those of ordinary skill in the art should understand that, in most cases, the effective value is used as a specific value to characterize the magnitude of an alternating current, without the need to know an instantaneous value of the alternating current. Correspondingly, the magnitude of an output voltage of the present invention also refers to the effective value of the voltage.

The first voltage is an output voltage, which is a differential voltage. Specifically, the first voltage on each phase is directly measurable with the electronic mutual inductor. For a target phase, if there is an input current on the primary side, there is always an induced voltage on the corresponding secondary side. There is no current on the primary side of either of the two reference phases, and, in an ideal state, the voltage on the secondary side of a reference phase should be zero, wherein, however, due to the interphase crosstalk between the target phase and the reference phase, there is an induced voltage on the secondary side of the reference phase. Thus, the existence of interphase crosstalk is further confirmed.

For a target phase, the first voltage on its secondary side is an actual output voltage not affected by crosstalk between the other phases.

Step 202: Based on each of the first voltages, determine the coefficient of mutual induction of the Rogowski coil of each phase, and the crosstalk induction of the Rogowski coils of each phase to the other two phases.

An exemplary explanation is as follows:

$$\{ \begin{matrix}{M}_{i 1} = \frac{{V}_{i 1\_ sec}}{2 π f \cdot {i}_{i 1\_ pri}} \\ {M}_{i 1 toi 2} = \frac{{V}_{i 2\_ sec}}{2 π f \cdot {i}_{i 1\_ pri}} \\ {M}_{i 1 toi 3} = \frac{{V}_{i 3\_ sec}}{2 π f \cdot {i}_{i 1\_ pri}}\end{matrix}$$

In the above formulae, Mᵢ₁ is the coefficient of mutual induction of the Rogowski coil of the target phase i1, Mᵢ₁ₜₒᵢ₂ is the crosstalk induction of the target phase i1 to the Rogowski coil of the reference phase i2, and Mᵢ₁ₜₒᵢ₃ is the crosstalk induction of the target phase i1 to the Rogowski coil of the reference phase i3. V_{i1_sec} represents the first voltage of the target phase i1, V_{i2_sec} represents the first voltage of the reference phase i2, and V_{i3_sec} represents the first voltage of the reference phase i3.

As a more specific explanation, when phase A is the target phase,

$$\{ \begin{matrix}{M}_{A} = \frac{{V}_{A \_ sec}}{2 π f \cdot {I}_{A \_ pri}} \\ {M}_{AtoB} = \frac{{V}_{B \_ sec}}{2 π f \cdot {I}_{A \_ pri}} \\ {M}_{AtoC} = \frac{{V}_{C \_ sec}}{2 π f \cdot {I}_{A \_ pri}}\end{matrix}$$

wherein M_{A} represents the coefficient of mutual induction of the Rogowski coil of phase A, M_{AtoB} represents the crosstalk induction of the Rogowski coil of phase A to phase B, M_{AtoC} represents the crosstalk induction of the Rogowski coil of phase A to phase C, I_{A_pri} represents a quantitative current of phase A, f represents the frequency of the quantitative current, V_{A_sec} represents a first voltage on the secondary side of phase A, V_{B_sec} represents a first voltage on the secondary side of phase B, and V_{C_sec} represents a first voltage on the secondary side of phase C.

When phase B is the target phase,

$$\{ \begin{matrix}{M}_{BtoA} = \frac{{V}_{A \_ sec}}{2 π f \cdot {I}_{{B}_{pri}}} \\ {M}_{B} = \frac{{V}_{B \_ sec}}{2 π f \cdot {I}_{{B}_{pri}}} \\ {M}_{BtoC} = \frac{{V}_{C \_ sec}}{2 π f \cdot {I}_{{B}_{pri}}}\end{matrix}$$

wherein M_{B} represents the coefficient of mutual induction of the Rogowski coil of phase B, M_{BtoA} represents the crosstalk induction of the Rogowski coil of phase B to phase A, M_{BtoC} represents the crosstalk induction of the Rogowski coil of phase B to phase C, I_{B_pri} represents a quantitative current of phase B, V_{A_sec} represents a first voltage on the secondary side of phase A, V_{B_sec} represents a first voltage on the secondary side of phase B, V_{C_sec} represents a first voltage on the secondary side of phase C, and f represents the frequency of the quantitative current.

When phase C is the target phase,

$$\{ \begin{matrix}{M}_{CtoA} = \frac{{V}_{A \_ sec}}{2 π f \cdot {I}_{C \_ pri}} \\ {M}_{CtoB} = \frac{{V}_{B \_ sec}}{2 π f \cdot {I}_{C \_ pri}} \\ {M}_{C} = \frac{{V}_{C \_ sec}}{2 π f \cdot {I}_{C \_ pri}}\end{matrix}$$

wherein M_{C} represents the coefficient of mutual induction of the Rogowski coil of phase C, M_{CtoA} represents the crosstalk induction of the Rogowski coil of phase C to phase A, M_{CtoB} represents the crosstalk induction of the Rogowski coil of phase C to phase B, I_{C_pri} represents a quantitative current of phase C, V_{A_sec} represents a first voltage on the secondary side of phase A, V_{B_sec} represents a first voltage on the secondary side of phase B, V_{C_sec} represents a first voltage on the secondary side of phase C, and f represents the frequency of the quantitative current.

Step 203: under the normal operating state of the electronic mutual inductor, measure the second voltage output on the secondary sides of each phase.

Under the normal operating state of the electronic mutual inductor, there is a current on the primary side of each phase, so the second voltage measured on the secondary side comprises the voltage generated by the Rogowski coil induction of that phase and the crosstalk voltage generated by the crosstalk of the other two phases to that phase. The second voltage is also the output voltage of that phase.

Step 204: Determine the compensation coefficient of the output voltage on the secondary side of each phase based on the second voltage, the coefficient of mutual induction, and the crosstalk induction of each phase.

The compensation coefficient may be acquired by the following theoretical derivation: assuming that the primary-side currents of the three phases are I_{A_pri}, I_{B_pri}, and I_{C_pri}, correspondingly, the second voltages of the three phases are V_{A_sec_meas}, V_{B_sec_meas}, and V_{C_sec_meas}.

Then,

$$[ \begin{matrix}{V}_{A \_ sec \_ meas} \\ {V}_{B \_ sec \_ meas} \\ {V}_{C \_ sec \_ meas}\end{matrix} ] = 2 π f \cdot [ \begin{matrix}{M}_{A} & {M}_{BtoA} & {M}_{CtoA} \\ {M}_{AtoB} & {M}_{B} & {M}_{CtoB} \\ {M}_{AtoC} & {M}_{BtoC} & {M}_{C}\end{matrix} ] \cdot [ \begin{matrix}{I}_{A \_ pri} \\ {I}_{B \_ pri} \\ {I}_{C \_ pri}\end{matrix} ] .$$

When there is no crosstalk, the second voltage matrix on the secondary side of each phase is

$$[ \begin{matrix}{V}_{A \_ sec \_ ideal} \\ {V}_{B \_ sec \_ ideal} \\ {V}_{C \_ sec \_ ideal}\end{matrix} ] = 2 π f \cdot [ \begin{matrix}{M}_{A} & 0 & 0 \\ 0 & {M}_{B} & 0 \\ 0 & 0 & {M}_{C}\end{matrix} ] \cdot [ \begin{matrix}{I}_{A \_ pri} \\ {I}_{B \_ pri} \\ {I}_{C \_ pri}\end{matrix} ] .$$

Therefore, the relationship between a case without crosstalk and a case with crosstalk is as follows:

$$[ \begin{matrix}{V}_{A \_ sec \_ ideal} \\ {V}_{B \_ sec \_ ideal} \\ {V}_{C \_ sec \_ ideal}\end{matrix} ] = [ \begin{matrix}{M}_{A} & 0 & 0 \\ 0 & {M}_{B} & 0 \\ 0 & 0 & {M}_{C}\end{matrix} ] \cdot {[ \begin{matrix}{M}_{A} & {M}_{BtoA} & {M}_{CtoA} \\ {M}_{AtoB} & {M}_{B} & {M}_{CtoB} \\ {M}_{AtoC} & {M}_{BtoC} & {M}_{C}\end{matrix} ]}^{- 1} \cdot [ \begin{matrix}{V}_{A \_ sec \_ meas} \\ {V}_{B \_ sec \_ meas} \\ {V}_{C \_ sec \_ meas}\end{matrix} ] .$$

In the above formula, V_{A_sec_ideal} represents the second voltage of phase A when it is not affected by interphase crosstalk, V_{B_sec_ideal} represents the second voltage of phase B when it is not affected by interphase crosstalk, and V_{C_sec_ideal} represents the second voltage of phase C when it is not affected by interphase crosstalk.

Correspondingly, the compensation coefficient is represented by the following matrix D:

$$D = [ \begin{matrix}{M}_{A} & 0 & 0 \\ 0 & {M}_{B} & 0 \\ 0 & 0 & {M}_{C}\end{matrix} ] \cdot {[ \begin{matrix}{M}_{A} & {M}_{BtoA} & {M}_{CtoA} \\ {M}_{AtoB} & {M}_{B} & {M}_{CtoB} \\ {M}_{AtoC} & {M}_{BtoC} & {M}_{C}\end{matrix} ]}^{- 1} = [ \begin{matrix}{Fct}_{A} & {Fct}_{BtoA} & {Fct}_{CtoA} \\ {Fct}_{AtoB} & {Fct}_{B} & {Fct}_{CtoB} \\ {Fct}_{AtoC} & {Fct}_{BtoC} & {Fct}_{C}\end{matrix} ]$$

$$wherein \{ \begin{matrix}{Fct}_{A} = \frac{{M}_{A} \cdot ( {M}_{B} \cdot {M}_{C} - {M}_{BtoC} \cdot {M}_{CtoB} )}{N} \\ {Fct}_{BtoA} = \frac{{M}_{A} \cdot ( {M}_{BtoC} \cdot {M}_{CtoA} - {M}_{BtoA} \cdot {M}_{C} )}{N} \\ {Fct}_{CtoA} = \frac{{M}_{A} \cdot ( {M}_{BtoA} \cdot {M}_{CtoB} - {M}_{B} \cdot {M}_{CtoA} )}{N} \\ {Fct}_{AtoB} = \frac{{M}_{B} \cdot ( {M}_{AtoC} \cdot {M}_{CtoB} - {M}_{AtoB} \cdot {M}_{C} )}{N} \\ {Fct}_{B} = \frac{{M}_{B} \cdot ( {M}_{A} \cdot {M}_{C} - {M}_{AtoC} \cdot {M}_{CtoA} )}{N} \\ {Fct}_{CtoB} = \frac{{M}_{B} \cdot ( {M}_{AtoB} \cdot {M}_{CtoA} - {M}_{A} \cdot {M}_{CtoB} )}{N} \\ {Fct}_{AtoC} = \frac{{M}_{C} \cdot ( {M}_{AtoB} \cdot {M}_{BtoC} - {M}_{AtoC} \cdot {M}_{B} )}{N} \\ {Fct}_{BtoC} = \frac{{M}_{C} \cdot ( {M}_{AtoC} \cdot {M}_{BtoA} - {M}_{A} \cdot {M}_{BtoC} )}{N} \\ {Fct}_{C} = \frac{{M}_{C} \cdot ( {M}_{A} \cdot {M}_{B} - {M}_{AtoB} \cdot {M}_{BtoA} )}{N}\end{matrix}$$

$$and N = {M}_{A} \cdot {M}_{B} \cdot {M}_{C} + {M}_{AtoC} \cdot {M}_{BtoA} \cdot {M}_{CtoB} + {M}_{CtoA} \cdot {M}_{AtoB} \cdot {M}_{BtoC} - {M}_{AtoC} \cdot {M}_{B} \cdot {M}_{CtoA} - {M}_{A} \cdot {M}_{BtoC} \cdot {M}_{CtoB} - {M}_{C} \cdot {M}_{AtoB} \cdot {M}_{BtoA} .$$

After the above-described compensation coefficients of each phase are input into the electronic mutual inductor, the electronic mutual inductor can compensate for the real-time output voltage values of the secondary sides of the phase based on the compensation coefficient, thereby acquiring a compensation voltage value, which is used to determine an actual current value of the primary side of the phase.

Specifically, the compensation voltage value may be acquired using the following formula:

$$\{ \begin{matrix}{V}_{A \_ comp} = {Fct}_{A} \cdot {V}_{A \_ meas} + {Fct}_{BtoA} \cdot {V}_{B \_ meas} + {Fct}_{CtoA} \cdot {V}_{C \_ meas} \\ {V}_{B \_ comp} = {Fct}_{AtoB} \cdot {V}_{A \_ meas} + {Fct}_{B} \cdot {V}_{B \_ meas} + {Fct}_{CtoB} \cdot {V}_{C \_ meas} \\ {V}_{C \_ comp} = {Fct}_{AtoC} \cdot {V}_{A \_ meas} + {Fct}_{BtoC} \cdot {V}_{B \_ meas} + {Fct}_{C} \cdot {V}_{C \_ meas}\end{matrix}$$

In the above formula, V_{A_comp} represents the compensation voltage value of phase A, V_{B_comp} represents the compensation voltage value of phase B, V_{C_comp} represents the compensation voltage value of phase C, V_{A_meas} represents a real-time output voltage value of the secondary sides of phase A, V_{B_meas} represents a real-time output voltage value of the secondary sides of phase B, and V_{C_meas} represents a real-time output voltage value of the secondary sides of phase C.

A real-time output voltage value as mentioned herein may be acquired by measurement, wherein, for example, the output terminal of each phase may be measured in real time by the electronic mutual inductor to acquire the output voltage of that phase.

Next, the electronic mutual inductor can send the compensation voltage value to a secondary-side device, which can use the compensation voltage value of each phase to determine the actual current value of the corresponding phase, for example, integrating the compensation voltage value to restore the actual current value of the primary side, and its specific method is prior art and will not be further described herein.

With a method according to this embodiment, a compensation coefficient matrix is determined by the derivation of physical formulae and then may be used to compensate for the real-time output voltage, so that the electronic mutual inductor acquires the actual current on the primary side, which is convenient, fast, and highly reliable.

### Embodiment 3

This embodiment provides a method for an electronic mutual inductor, and the method is executed mainly by an electronic mutual inductor. The electronic mutual inductor is provided with three phases each having a Rogowski coil, and the electronic mutual inductor is used to convert a current of a primary-side device into a secondary-side voltage.

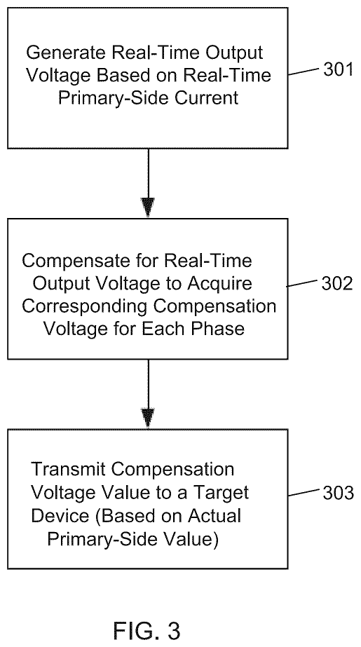

Refer to FIG. 3, which is a flowchart of a method for an electronic mutual inductor according to this embodiment. The method comprises:

Step 301: Generate a real-time output voltage of the corresponding phase based on the real-time current of each phase of the primary-side device.

This step is based on the prior art and will not be further described herein.

Step 302: According to a predetermined compensation coefficient for each phase, compensate for the real-time output voltage on each phase to acquire the corresponding compensation voltage value for each phase, wherein the compensation coefficient is determined based on the coefficient of mutual induction of the Rogowski coil of each phase and the crosstalk induction of each phase to the Rogowski coils of the other phases.

The compensation coefficient may be set in advance, wherein, for example, before shipment from a factory, the compensation coefficient for each phase is determined based on the mutual inductance of the Rogowski coil of each phase and the crosstalk induction of each phase to the Rogowski coils of the other phases, and then, the compensation coefficient is input into the electronic mutual inductor so that the electronic mutual inductor compensates for the acquired real-time output voltage of each phase.

Step 303: Send the compensation voltage value to a target device, the compensation voltage value corresponding to an actual current value of the primary-side device.

The target device may be a secondary-side device, which, after receiving the compensation voltage value, can determine the actual current value of the primary side based on the compensation voltage value, wherein, for example, corresponding operations may be performed based on the monitoring of the actual current value of the primary side, and, indeed, some operations may also be directly performed based on the acquired compensation voltage value, which will not be further described herein.

According to this embodiment, by a predetermined compensation coefficient of the voltage of each phase of the electronic mutual inductor, the electronic mutual inductor can compensate for the real-time voltage value output on the secondary side, thereby correcting the real-time voltage value and accurately reflecting the actual situation of the primary-side device.

### Embodiment 4

In this embodiment, a method for an electronic mutual inductor in embodiment 3 is further explained. In this embodiment, mainly a supplementary explanation on how to determine the compensation coefficient is provided.

Specifically, as shown in the above embodiments, the compensation coefficient may be determined by:
when a quantitative current is applied, in turn, to the primary side of one phase, acquiring a first voltage output from the secondary side of each phase while keeping the primary side of the other two phases currentless; based on each of the first voltages, determining a coefficient of mutual induction of the Rogowski coil of each phase, and the crosstalk induction of the Rogowski coil of each phase to the other two phases.

More specifically, the compensation coefficient is determined as follows:
the three phases of the electronic mutual inductor are phase A, phase B, and phase C, respectively, wherein, when a quantitative current is applied to phase A, and phase B and phase C are kept currentless,

$$\{ \begin{matrix}{M}_{A} = \frac{{V}_{A \_ sec}}{2 π f \cdot {I}_{A \_ pri}} \\ {M}_{AtoB} = \frac{{V}_{B \_ sec}}{2 π f \cdot {I}_{A \_ pri}} \\ {M}_{AtoC} = \frac{{V}_{C \_ sec}}{2 π f \cdot {I}_{A \_ pri}}\end{matrix}$$

wherein M_{A} represents the coefficient of mutual induction of the Rogowski coil of phase A, M_{AtoB} represents the crosstalk induction of the Rogowski coil of phase A to phase B, M_{AtoC} represents the crosstalk induction of the Rogowski coil of phase A to phase C, I_{A_pri} represents a quantitative current of phase A, f represents the frequency of the quantitative current, V_{A_sec} represents a first voltage on the secondary side of phase A, V_{B_sec} represents a first voltage on the secondary side of phase B, and V_{C_sec} represents a first voltage on the secondary side of phase C;
under the condition of applying a quantitative current to phase B and keeping phase A and phase C currentless,

$$\{ \begin{matrix}{M}_{BtoA} = \frac{{V}_{A \_ sec}}{2 π f \cdot {I}_{{B}_{pri}}} \\ {M}_{B} = \frac{{V}_{B \_ sec}}{2 π f \cdot {I}_{{B}_{pri}}} \\ {M}_{BtoC} = \frac{{V}_{C \_ sec}}{2 π f \cdot {I}_{{B}_{pri}}}\end{matrix}$$

wherein M_{B} represents the coefficient of mutual induction of the Rogowski coil of phase B, M_{BtoA} represents the crosstalk induction of phase B to the Rogowski coil of phase A, M_{BtoC} represents the crosstalk induction of phase B to the Rogowski coil of phase C, and I_{B_pri} represents a quantitative current of phase B;
under a condition of applying a quantitative current to phase C and keeping phase A and phase B currentless,

$$\{ \begin{matrix}{M}_{CtoA} = \frac{{V}_{A \_ sec}}{2 π f \cdot {I}_{C \_ pri}} \\ {M}_{CtoB} = \frac{{V}_{B \_ sec}}{2 π f \cdot {I}_{C \_ pri}} \\ {M}_{C} = \frac{{V}_{C \_ sec}}{2 π f \cdot {I}_{C \_ pri}}\end{matrix}$$

wherein M_{C} represents the coefficient of mutual induction of the Rogowski coil of phase C, M_{CtoA} represents the crosstalk induction of phase C to the Rogowski coil of phase A, M_{CtoB} represents the crosstalk induction of phase C to the Rogowski coil of phase B, and I_{C_pri} represents a quantitative current of phase C.

Optionally, acquiring a compensation coefficient for an output voltage of the secondary side of that phase comprises:
under the normal operating state of the electronic mutual inductor, measuring the second voltage output on the secondary side of each phase, the second voltage comprising an induced voltage generated by the Rogowski coil induction of the phase and a crosstalk voltage generated by the crosstalk of the other two phases to the phase;
determining the compensation coefficient of the output voltage on the secondary side of each phase based on the second voltage, the coefficient of mutual induction, and the crosstalk induction of each phase.

More specifically, the compensation coefficient of the second voltage output on the secondary side is determined according to the following formula:

$$D = [ \begin{matrix}{Fct}_{A} & {Fct}_{BtoA} & {Fct}_{CtoA} \\ {Fct}_{AtoB} & {Fct}_{B} & {Fct}_{CtoB} \\ {Fct}_{AtoC} & {Fct}_{BtoC} & {Fct}_{C}\end{matrix} ]$$

$$\{ \begin{matrix}{Fct}_{A} = \frac{{M}_{A} \cdot ( {M}_{B} \cdot {M}_{C} - {M}_{BtoC} \cdot {M}_{CtoB} )}{N} \\ {Fct}_{BtoA} = \frac{{M}_{A} \cdot ( {M}_{BtoC} \cdot {M}_{CtoA} - {M}_{BtoA} \cdot {M}_{C} )}{N} \\ {Fct}_{CtoA} = \frac{{M}_{A} \cdot ( {M}_{BtoA} \cdot {M}_{CtoB} - {M}_{B} \cdot {M}_{CtoA} )}{N} \\ {Fct}_{AtoB} = \frac{{M}_{B} \cdot ( {M}_{AtoC} \cdot {M}_{CtoB} - {M}_{AtoB} \cdot {M}_{C} )}{N} \\ {Fct}_{B} = \frac{{M}_{B} \cdot ( {M}_{A} \cdot {M}_{C} - {M}_{AtoC} \cdot {M}_{CtoA} )}{N} \\ {Fct}_{CtoB} = \frac{{M}_{B} \cdot ( {M}_{AtoB} \cdot {M}_{CtoA} - {M}_{A} \cdot {M}_{CtoB} )}{N} \\ {Fct}_{AtoC} = \frac{{M}_{C} \cdot ( {M}_{AtoB} \cdot {M}_{BtoC} - {M}_{AtoC} \cdot {M}_{B} )}{N} \\ {Fct}_{BtoC} = \frac{{M}_{C} \cdot ( {M}_{AtoC} \cdot {M}_{BtoA} - {M}_{A} \cdot {M}_{BtoC} )}{N} \\ {Fct}_{C} = \frac{{M}_{C} \cdot ( {M}_{A} \cdot {M}_{B} - {M}_{AtoB} \cdot {M}_{BtoA} )}{N}\end{matrix}$$

$$and N = {M}_{A} \cdot {M}_{B} \cdot {M}_{C} + {M}_{AtoC} \cdot {M}_{BtoA} \cdot {M}_{CtoB} + {M}_{CtoA} \cdot {M}_{AtoB} \cdot {M}_{BtoC} - {M}_{AtoC} \cdot {M}_{B} \cdot {M}_{CtoA} - {M}_{A} \cdot {M}_{BtoC} \cdot {M}_{CtoB} - {M}_{C} \cdot {M}_{AtoB} \cdot {M}_{BtoA} .$$

The compensation coefficient may be input into the electronic mutual inductor in advance so that the electronic mutual inductor compensates for the real-time output voltage value of each phase based on a predetermined compensation coefficient of each phase, and acquires the corresponding compensation voltage value for each phase, which comprises:

$$\{ \begin{matrix}{V}_{A \_ comp} = {Fct}_{A} \cdot {V}_{A \_ meas} + {Fct}_{BtoA} \cdot {V}_{B \_ meas} + {Fct}_{CtoA} \cdot {V}_{C \_ meas} \\ {V}_{B \_ comp} = {Fct}_{AtoB} \cdot {V}_{A \_ meas} + {Fct}_{B} \cdot {V}_{B \_ meas} + {Fct}_{CtoB} \cdot {V}_{C \_ meas} \\ {V}_{C \_ comp} = {Fct}_{AtoC} \cdot {V}_{A \_ meas} + {Fct}_{BtoC} \cdot {V}_{B \_ meas} + {Fct}_{C} \cdot {V}_{C \_ meas}\end{matrix}$$

V_{A_comp} represents the compensation voltage value of phase A, V_{B_comp} represents the compensation voltage value of phase B, V_{C_comp} represents the compensation voltage value of phase C, V_{A_meas} represents a real-time output voltage value of the secondary sides of phase A, V_{B_meas} represents a real-time output voltage value of the secondary sides of phase B, and V_{C_meas} represents a real-time output voltage value of the secondary sides of phase C.

A voltage measured in real time for each phase is compensated for by using the compensation coefficient or compensation formula of this embodiment, which provides a high level of timeliness and high universality, and allows the acquisition of more accurate real-time information about the primary-side device.

### Embodiment 5

This embodiment provides an apparatus for an electronic mutual inductor, wherein the electronic mutual inductor is provided with three phases each having a Rogowski coil, and the electronic mutual inductor is used to convert a current of a primary side device into a secondary-side voltage. The apparatus for an electronic mutual inductor executes the method for an electronic mutual inductor in embodiments 1 and 2.

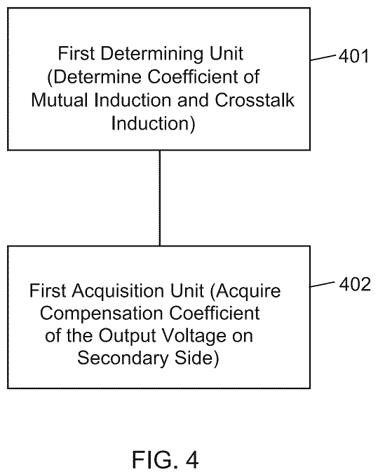

Refer to FIG. 4, which is a structural schematic diagram of an apparatus for an electronic mutual inductor according to this embodiment.

The electronic mutual inductor comprises a first determining unit 401 and a first acquisition unit 402. The first determining unit 401 is used to determine the coefficient of mutual induction of each phase of the Rogowski coil of the electronic mutual inductor and determining the crosstalk induction of each phase to the Rogowski coils of the other phases; the first acquisition unit 402 is used to acquire a compensation coefficient of the output voltage on the secondary side of each phase based on the corresponding coefficient of mutual induction and crosstalk induction, wherein the compensation coefficient is used to compensate for the real-time output voltage value on the secondary side of the electronic mutual inductor to acquire a compensation voltage value, the compensation voltage value corresponding to an actual current value on the primary side.

Optionally, the first determining unit 401 is specifically used for:
the three phases of the electronic mutual inductor are phase A, phase B, and phase C, respectively, wherein, when a quantitative current is applied to phase A, and phase B and phase C are kept currentless,

$$\{ \begin{matrix}{M}_{A} = \frac{{V}_{A \_ sec}}{2 π f \cdot {I}_{A \_ pri}} \\ {M}_{AtoB} = \frac{{V}_{B \_ sec}}{2 π f \cdot {I}_{A \_ pri}} \\ {M}_{AtoC} = \frac{{V}_{C \_ sec}}{2 π f \cdot {I}_{A \_ pri}}\end{matrix}$$

wherein M_{A} represents the coefficient of mutual induction of the Rogowski coil of phase A, M_{AtoB} represents the crosstalk induction of the Rogowski coil of phase A to phase B, M_{AtoC} represents the crosstalk induction of the Rogowski coil of phase A to phase C, I_{A_pri} represents a quantitative current of phase A, f represents the frequency of the quantitative current, V_{A_sec} represents a first voltage on the secondary side of phase A, V_{B_sec} represents a first voltage on the secondary side of phase B, and V_{C_sec} represents a first voltage on the secondary side of phase C;
under the condition of applying a quantitative current to phase B and keeping phase A and phase C currentless,

$$\{ \begin{matrix}{M}_{BtoA} = \frac{{V}_{A \_ sec}}{2 π f \cdot {I}_{{B}_{pri}}} \\ {M}_{B} = \frac{{V}_{B \_ sec}}{2 π f \cdot {I}_{{B}_{pri}}} \\ {M}_{BtoC} = \frac{{V}_{C \_ sec}}{2 π f \cdot {I}_{{B}_{pri}}}\end{matrix}$$

wherein M_{B} represents the coefficient of mutual induction of the Rogowski coil of phase B, M_{BtoA} represents the crosstalk induction of phase B to the Rogowski coil of phase A, M_{BtoC} represents the crosstalk induction of phase B to the Rogowski coil of phase C, and I_{B_pri} represents a quantitative current of phase B;
under a condition of applying a quantitative current to phase C and keeping phase A and phase B currentless,

$$\{ \begin{matrix}{M}_{CtoA} = \frac{{V}_{A \_ sec}}{2 π f \cdot {I}_{C \_ pri}} \\ {M}_{CtoB} = \frac{{V}_{B \_ sec}}{2 π f \cdot {I}_{C \_ pri}} \\ {M}_{C} = \frac{{V}_{C \_ sec}}{2 π f \cdot {I}_{C \_ pri}}\end{matrix}$$

wherein M_{C} represents the coefficient of mutual induction of the Rogowski coil of phase C, M_{CtoA} represents the crosstalk induction of phase C to the Rogowski coil of phase A, M_{CtoB} represents the crosstalk induction of phase C to the Rogowski coil of phase B, and I_{C_pri} represents a quantitative current of phase C.

Correspondingly, the first acquisition unit 402 is specifically used to:
determine a compensation coefficient matrix D according to the following formula:

$$D = [ \begin{matrix}{Fct}_{A} & {Fct}_{BtoA} & {Fct}_{CtoA} \\ {Fct}_{AtoB} & {Fct}_{B} & {Fct}_{CtoB} \\ {Fct}_{AtoC} & {Fct}_{BtoC} & {Fct}_{C}\end{matrix} ]$$

$$\{ \begin{matrix}{Fct}_{A} = \frac{{M}_{A} \cdot ( {M}_{B} \cdot {M}_{C} - {M}_{BtoC} \cdot {M}_{CtoB} )}{N} \\ {Fct}_{BtoA} = \frac{{M}_{A} \cdot ( {M}_{BtoC} \cdot {M}_{CtoA} - {M}_{BtoA} \cdot {M}_{C} )}{N} \\ {Fct}_{CtoA} = \frac{{M}_{A} \cdot ( {M}_{BtoA} \cdot {M}_{CtoB} - {M}_{B} \cdot {M}_{CtoA} )}{N} \\ {Fct}_{AtoB} = \frac{{M}_{B} \cdot ( {M}_{AtoC} \cdot {M}_{CtoB} - {M}_{AtoB} \cdot {M}_{C} )}{N} \\ {Fct}_{B} = \frac{{M}_{B} \cdot ( {M}_{A} \cdot {M}_{C} - {M}_{AtoC} \cdot {M}_{CtoA} )}{N} \\ {Fct}_{CtoB} = \frac{{M}_{B} \cdot ( {M}_{AtoB} \cdot {M}_{CtoA} - {M}_{A} \cdot {M}_{CtoB} )}{N} \\ {Fct}_{AtoC} = \frac{{M}_{C} \cdot ( {M}_{AtoB} \cdot {M}_{BtoC} - {M}_{AtoC} \cdot {M}_{B} )}{N} \\ {Fct}_{BtoC} = \frac{{M}_{C} \cdot ( {M}_{AtoC} \cdot {M}_{BtoA} - {M}_{A} \cdot {M}_{BtoC} )}{N} \\ {Fct}_{C} = \frac{{M}_{C} \cdot ( {M}_{A} \cdot {M}_{B} - {M}_{AtoB} \cdot {M}_{BtoA} )}{N}\end{matrix}$$

$$and N = {M}_{A} \cdot {M}_{B} \cdot {M}_{C} + {M}_{AtoC} \cdot {M}_{BtoA} \cdot {M}_{CtoB} + {M}_{CtoA} \cdot {M}_{AtoB} \cdot {M}_{BtoC} - {M}_{AtoC} \cdot {M}_{B} \cdot {M}_{CtoA} - {M}_{A} \cdot {M}_{BtoC} \cdot {M}_{CtoB} - {M}_{C} \cdot {M}_{AtoB} \cdot {M}_{BtoA} .$$

The compensation coefficient matrix D is acquired by the following theoretical derivation:
assuming that the primary-side currents of the three phases are I_{A_pri}, I_{B_pri}, and I_{C_pri}, correspondingly, the second voltages of the three phases are V_{A_sec_meas}, V_{B_sec_meas}, and V_{C_sec_meas}.

Then,

$$[ \begin{matrix}{V}_{A \_ sec \_ meas} \\ {V}_{B \_ sec \_ meas} \\ {V}_{C \_ sec \_ meas}\end{matrix} ] = 2 π f \cdot [ \begin{matrix}{M}_{A} & {M}_{BtoA} & {M}_{CtoA} \\ {M}_{AtoB} & {M}_{B} & {M}_{CtoB} \\ {M}_{AtoC} & {M}_{BtoC} & {M}_{C}\end{matrix} ] \cdot [ \begin{matrix}{I}_{A \_ pri} \\ {I}_{B \_ pri} \\ {I}_{C \_ pri}\end{matrix} ] .$$

When there is no crosstalk, the second voltage matrix on the secondary side of each phase is

$$[ \begin{matrix}{V}_{A \_ sec \_ ideal} \\ {V}_{B \_ sec \_ ideal} \\ {V}_{C \_ sec \_ ideal}\end{matrix} ] = 2 π f \cdot [ \begin{matrix}{M}_{A} & 0 & 0 \\ 0 & {M}_{B} & 0 \\ 0 & 0 & {M}_{C}\end{matrix} ] \cdot [ \begin{matrix}{I}_{A \_ pri} \\ {I}_{B \_ pri} \\ {I}_{C \_ pri}\end{matrix} ] .$$

Therefore, the relationship between a case without crosstalk and a case with crosstalk is as follows:

$$[ \begin{matrix}{V}_{A \_ sec \_ ideal} \\ {V}_{B \_ sec \_ ideal} \\ {V}_{C \_ sec \_ ideal}\end{matrix} ] = [ \begin{matrix}{M}_{A} & 0 & 0 \\ 0 & {M}_{B} & 0 \\ 0 & 0 & {M}_{C}\end{matrix} ] \cdot {[ \begin{matrix}{M}_{A} & {M}_{BtoA} & {M}_{CtoA} \\ {M}_{AtoB} & {M}_{B} & {M}_{CtoB} \\ {M}_{AtoC} & {M}_{BtoC} & {M}_{C}\end{matrix} ]}^{- 1} \cdot [ \begin{matrix}{V}_{A \_ sec \_ meas} \\ {V}_{B \_ sec \_ meas} \\ {V}_{C \_ sec \_ meas}\end{matrix} ] .$$

In the above formula, V_{A_sec_ideal} represents the second voltage of phase A when it is not affected by interphase crosstalk, V_{B_sec_ideal} represents the second voltage of phase B when it is not affected by interphase crosstalk, and V_{C_sec_ideal} represents the second voltage of phase C when it is not affected by interphase crosstalk.

The operating principles of each unit in this embodiment are the same as those in the above-described embodiments, which will not be further described herein.

According to this embodiment, the corresponding compensation coefficient may be determined in advance based on the coefficient of mutual induction and crosstalk induction of the secondary side, and then the electronic mutual inductor can compensate for the real-time output voltage value of the secondary side by the compensation coefficient, wherein the acquired compensation voltage value corresponds to the actual current value of the primary-side device, providing a method that is highly universal and delivers high real-time performance.

### Embodiment 6

This embodiment provides an electronic mutual inductor for executing a method for an electronic mutual inductor as described in embodiments 3 and 4.

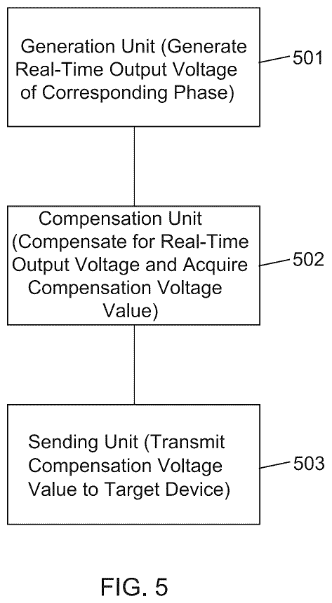

Refer to FIG. 5, which is a schematic diagram of the structure of an electronic mutual inductor according to this embodiment. The electronic mutual inductor comprises a generation unit 501, a compensation unit 502, and a sending unit 503.

The generating unit 501 is used to, based on the real-time current of each phase of the primary-side device, generate a real-time output voltage of the corresponding phase; the compensation unit 502 is used to compensate for the real-time output voltage on each phase based on a predetermined compensation coefficient of each phase, and acquire the corresponding compensation voltage value for each phase, wherein the compensation coefficient is determined based on the coefficient of mutual induction of the Rogowski coil of each phase and the crosstalk induction of the Rogowski coil of each phase to the other phases; the sending unit 503 is used to send the compensation voltage value to a target device, the compensation voltage value corresponding to an actual current value of the primary-side device.

As an example, the compensation coefficient matrix D is:

$$D = [ \begin{matrix}{Fct}_{A} & {Fct}_{BtoA} & {Fct}_{CtoA} \\ {Fct}_{AtoB} & {Fct}_{B} & {Fct}_{CtoB} \\ {Fct}_{AtoC} & {Fct}_{BtoC} & {Fct}_{C}\end{matrix} ]$$

$$\{ \begin{matrix}{Fct}_{A} = \frac{{M}_{A} \cdot ( {M}_{B} \cdot {M}_{C} - {M}_{BtoC} \cdot {M}_{CtoB} )}{N} \\ {Fct}_{BtoA} = \frac{{M}_{A} \cdot ( {M}_{BtoC} \cdot {M}_{CtoA} - {M}_{BtoA} \cdot {M}_{C} )}{N} \\ {Fct}_{CtoA} = \frac{{M}_{A} \cdot ( {M}_{BtoA} \cdot {M}_{CtoB} - {M}_{B} \cdot {M}_{CtoA} )}{N} \\ {Fct}_{AtoB} = \frac{{M}_{B} \cdot ( {M}_{AtoC} \cdot {M}_{CtoB} - {M}_{AtoB} \cdot {M}_{C} )}{N} \\ {Fct}_{B} = \frac{{M}_{B} \cdot ( {M}_{A} \cdot {M}_{C} - {M}_{AtoC} \cdot {M}_{CtoA} )}{N} \\ {Fct}_{CtoB} = \frac{{M}_{B} \cdot ( {M}_{AtoB} \cdot {M}_{CtoA} - {M}_{A} \cdot {M}_{CtoB} )}{N} \\ {Fct}_{AtoC} = \frac{{M}_{C} \cdot ( {M}_{AtoB} \cdot {M}_{BtoC} - {M}_{AtoC} \cdot {M}_{B} )}{N} \\ {Fct}_{BtoC} = \frac{{M}_{C} \cdot ( {M}_{AtoC} \cdot {M}_{BtoA} - {M}_{A} \cdot {M}_{BtoC} )}{N} \\ {Fct}_{C} = \frac{{M}_{C} \cdot ( {M}_{A} \cdot {M}_{B} - {M}_{AtoB} \cdot {M}_{BtoA} )}{N}\end{matrix}$$

$$and$$

$$N = {M}_{A} \cdot {M}_{B} \cdot {M}_{C} + {M}_{AtoC} \cdot {M}_{BtoA} \cdot {M}_{CtoB} + {M}_{CtoA} \cdot {M}_{AtoB} \cdot {M}_{BtoC} - {M}_{AtoC} \cdot {M}_{B} \cdot {M}_{CtoA} - {M}_{A} \cdot {M}_{BtoC} \cdot {M}_{CtoB} - {M}_{C} \cdot {M}_{AtoB} \cdot {M}_{BtoA} ;$$

wherein M_{A} represents the coefficient of mutual induction of the Rogowski coil of phase A, M_{AtoB} represents the crosstalk induction of the Rogowski coil of phase A to phase B, M_{AtoC} represents the crosstalk induction of the Rogowski coil of phase A to phase C, I_{A_pri} represents a quantitative current of phase A, f represents the frequency of the quantitative current, V_{A_sec} represents a first voltage on the secondary side of phase A, V_{B_sec} represents a first voltage on the secondary side of phase B, and V_{C_sec} represents a first voltage on the secondary side of phase C;
M_{B} represents the coefficient of mutual induction of the Rogowski coil of phase B, M_{BtoA} represents the crosstalk induction of phase B to the Rogowski coil of phase A, M_{BtoC} represents the crosstalk induction of phase B to the Rogowski coil of phase C, and I_{B_pri} represents a quantitative current of phase B;
M_{C} represents the coefficient of mutual induction of the Rogowski coil of phase C, M_{CtoA} represents the crosstalk induction of phase C to the Rogowski coil of phase A, M_{CtoB} represents the crosstalk induction of phase C to the Rogowski coil of phase B, and I_{C_pri} represents a quantitative current of phase C.

Correspondingly, the compensation unit 502 is specifically used to:
compensate for a real-time output voltage of each phase by using the following formula:

$$\{ \begin{matrix}{V}_{A \_ comp} = {Fct}_{A} \cdot {V}_{A \_ meas} + {Fct}_{BtoA} \cdot {V}_{B \_ meas} + {Fct}_{CtoA} \cdot {V}_{C \_ meas} \\ {V}_{B \_ comp} = {Fct}_{AtoB} \cdot {V}_{A \_ meas} + {Fct}_{B} \cdot {V}_{B \_ meas} + {Fct}_{CtoB} \cdot {V}_{C \_ meas} \\ {V}_{C \_ comp} = {Fct}_{AtoC} \cdot {V}_{A \_ meas} + {Fct}_{BtoC} \cdot {V}_{B \_ meas} + {Fct}_{C} \cdot {V}_{C \_ meas}\end{matrix}$$

V_{A_comp} represents the compensation voltage value of phase A, V_{B_comp} represents the compensation voltage value of phase B, V_{C_comp} represents the compensation voltage value of phase C, V_{A_meas} represents a real-time output voltage value of the secondary sides of phase A, V_{B_meas} represents a real-time output voltage value of the secondary sides of phase B, and V_{C_meas} represents a real-time output voltage value of the secondary sides of phase C.

The generation unit 501 is based on the prior art. The operating principles of the other units are the same as those in the above-described embodiments, which will not be further described herein.

A voltage measured in real time for each phase is compensated for by using the compensation coefficient or compensation formula of this embodiment, which provides a high level of timeliness and high universality, and allows the acquisition of more accurate real-time information about the primary-side device.

The present invention further provides an apparatus for an electronic mutual inductor, wherein the electronic mutual inductor is provided with three phases each having a Rogowski coil, the electronic mutual inductor is used to convert a current of a primary-side device into a secondary-side voltage, and the apparatus for an electronic mutual inductor comprises at least one memory and at least one processor. The memory is used to store an instruction. The processor is used to execute a method for an electronic mutual inductor as described in any of the above-described embodiments according to an instruction stored in the memory.

The present invention further provides an electronic mutual inductor, which is provided with three phases each having a Rogowski coil and is used to convert a current of a primary side device into a secondary-side voltage, wherein the apparatus comprises: at least one memory, used to store an instruction; at least one processor used to, according to an instruction stored in the memory, execute any one of the above-described methods for an electronic mutual inductor. An embodiment of the present invention further provides a readable storage medium. The readable storage medium stores a machine-readable instruction, and when the machine-readable instruction is executed by a machine, the machine executes a method for an electronic mutual inductor as described in any of the above-described embodiments.

The readable medium stores a machine-readable instruction that, when executed by a processor, causes the processor to execute any of the above-described methods. Specifically, a system or apparatus equipped with a readable storage medium may be provided; software program code realizing a function of any one of the embodiments above is stored on the readable storage medium, and a computer or processor of the system or apparatus is caused to read and execute a machine-readable instruction stored in the readable storage medium.

In this case, the functions of any of the above embodiments may be performed by a program code read from the readable medium, so a machine-readable code and a readable storage medium for storing machine-readable code constitute a part of the present invention.

Examples of readable storage media include floppy disks, hard disks, magneto-optical disks, optical disks (such as CD-ROM, CD-R, CD-RW, DVD-ROM, DVD-RAM, DVD-RW, DVD+RW), magnetic tapes, non-volatile memory cards and ROM. Optionally, the program code may be downloaded from a server computer or a cloud via a communication network.

Those skilled in the art should understand that various changes in form and amendments may be made to the embodiments disclosed above without departing from the substance of the invention. Thus, the scope of protection of the present invention shall be defined by the attached claims.

It should be noted that not all steps and units in the above-described process flows and system structure diagrams are necessary, and some steps or units may be omitted according to actual needs. The sequence in which the steps are executed is not fixed, but may be adjusted as needed. The apparatus structure described in the above embodiments may be either a physical structure or a logical structure, which means that some units may be implemented by the same physical entity, or some units may be implemented by a plurality of physical entities separately or by some parts of a plurality of independent devices jointly.

In the embodiments above, a hardware unit may be realized in a mechanical or an electrical manner. For example, a hardware unit or processor may comprise a permanently dedicated circuit or logic (for example, a specialized processor, FPGA, or ASIC) to complete corresponding operations. A hardware unit or processor may further comprise programmable logic or circuits (such as general-purpose processors or other programmable processors), which may be temporarily set by software to complete corresponding operations. Particular embodiments (mechanical, or dedicated permanent circuitry, or temporarily set circuitry) may be determined based on considerations of cost and time.

What have been described above are only preferred embodiments of the present invention, rather than being intended to limit the present invention, and any modifications, equivalent substitutions, improvements, etc., made thereto within the spirit and principles of the present invention should be included in the scope of protection of the present invention.

1-17. (canceled)

18. A method for electronic mutual inductance, the method comprising:
providing an electronic mutual inductor with three phases each having a Rogowski coil, and wherein the electronic mutual inductor is configured to convert a current of a primary-side device into a secondary-side voltage;
determining a coefficient of mutual induction of the Rogowski coil of each phase of the electronic mutual inductor and determining crosstalk induction of each phase to Rogowski coils of other phases;
based on the corresponding coefficient of mutual induction and the crosstalk induction of each phase, acquiring a compensation coefficient for an output voltage of the secondary side of that phase, and using the compensation coefficient to compensate for a real-time output voltage value of the secondary side of the electronic mutual inductor to acquire a compensation voltage value that corresponds to an actual current value of the primary-side device.

19. The method according to claim 18, wherein the steps of determining the coefficient of mutual induction of the Rogowski coil of each phase and determining the crosstalk induction of each phase to the Rogowski coils of the other phases comprises:
when a quantitative current is applied, in turn, to the primary side of one phase, acquiring a first voltage output from the secondary side of each phase while keeping the primary side of the other two phases currentless;
based on each of the first voltages, determining a coefficient of mutual induction of the Rogowski coil of each phase, and the crosstalk induction of the Rogowski coil of each phase to the other two phases.

20. The method according to claim 18, wherein the coefficient of mutual induction of the Rogowski coil of each phase is determined according to the following formula, and wherein the crosstalk induction of each phase to the Rogowski coil of each of said reference phases comprises:
three phases of the electronic mutual inductor are phase A, phase B, and phase C, respectively, wherein, when the quantitative current is applied to phase A, and phase B and phase C are kept currentless,
$$\{ \begin{matrix}{M}_{A} = \frac{{V}_{A \_ sec}}{2 π f \cdot {I}_{A \_ pri}} \\ {M}_{AtoB} = \frac{{V}_{B \_ sec}}{2 π f \cdot {I}_{A \_ pri}} \\ {M}_{AtoC} = \frac{{V}_{C \_ sec}}{2 π f \cdot {I}_{A \_ pri}}\end{matrix}$$
wherein M_{A} represents the coefficient of mutual induction of the Rogowski coil of phase A, M_{AtoB} represents the crosstalk induction of the Rogowski coil of phase A to phase B, M_{AtoC} represents the crosstalk induction of the Rogowski coil of phase A to phase C, I_{A_pri} represents a quantitative current of phase A, f represents the frequency of the quantitative current, V_{A_sec} represents a first voltage on the secondary side of phase A, V_{B_sec} represents a first voltage on the secondary side of phase B, and V_{C_sec} represents a first voltage on the secondary side of phase C;
under a condition of applying a quantitative current to phase B and keeping phase A and phase C currentless,
$$\{ \begin{matrix}{M}_{BtoA} = \frac{{V}_{A \_ sec}}{2 π f \cdot {I}_{{B}_{pri}}} \\ {M}_{B} = \frac{{V}_{B \_ sec}}{2 π f \cdot {I}_{{B}_{pri}}} \\ {M}_{BtoC} = \frac{{V}_{C \_ sec}}{2 π f \cdot {I}_{{B}_{pri}}}\end{matrix}$$
wherein M_{B} represents the coefficient of mutual induction of the Rogowski coil of phase B, M_{BtoA} represents the crosstalk induction of phase B to the Rogowski coil of phase A, M_{BtoC} represents the crosstalk induction of phase B to the Rogowski coil of phase C, and I_{B_pri} represents a quantitative current of phase B;
under a condition of applying a quantitative current to phase C and keeping phases A and B currentless,
$$\{ \begin{matrix}{M}_{CtoA} = \frac{{V}_{A \_ sec}}{2 π f \cdot {I}_{C \_ pri}} \\ {M}_{CtoB} = \frac{{V}_{B \_ sec}}{2 π f \cdot {I}_{C \_ pri}} \\ {M}_{C} = \frac{{V}_{C \_ sec}}{2 π f \cdot {I}_{C \_ pri}}\end{matrix}$$
wherein M_{C} represents the coefficient of mutual induction of the Rogowski coil of phase C, M_{CtoA} represents the crosstalk induction of phase C to the Rogowski coil of phase A, M_{CtoB} represents the crosstalk induction of phase C to the Rogowski coil of phase B, and I_{C_pri} represents a quantitative current of phase C.

21. The method according to claim 20, wherein, based on the corresponding coefficient of mutual induction and the crosstalk induction of each phase, acquiring a compensation coefficient for an output voltage of the secondary side of that phase comprises:
under the normal operating state of the electronic mutual inductor, measuring a second voltage output on the secondary side of each phase, the second voltage comprising an induced voltage generated by the Rogowski coil induction of the phase and a crosstalk voltage generated by the crosstalk of the other two phases to the phase; and
determining the compensation coefficient of the output voltage on the secondary side of each phase based on the second voltage, the coefficient of mutual induction, and the crosstalk induction of each phase.

22. The method according to claim 18, which comprises determining a compensation coefficient matrix D according to the following formula:
$$D = [ \begin{matrix}{Fct}_{A} & {Fct}_{BtoA} & {Fct}_{CtoA} \\ {Fct}_{AtoB} & {Fct}_{B} & {Fct}_{CtoB} \\ {Fct}_{AtoC} & {Fct}_{BtoC} & {Fct}_{C}\end{matrix} ]$$
$$\{ \begin{matrix}{Fct}_{A} = \frac{{M}_{A} \cdot ( {M}_{B} \cdot {M}_{C} - {M}_{BtoC} \cdot {M}_{CtoB} )}{N} \\ {Fct}_{BtoA} = \frac{{M}_{A} \cdot ( {M}_{BtoC} \cdot {M}_{CtoA} - {M}_{BtoA} \cdot {M}_{C} )}{N} \\ {Fct}_{CtoA} = \frac{{M}_{A} \cdot ( {M}_{BtoA} \cdot {M}_{CtoB} - {M}_{B} \cdot {M}_{CtoA} )}{N} \\ {Fct}_{AtoB} = \frac{{M}_{B} \cdot ( {M}_{AtoC} \cdot {M}_{CtoB} - {M}_{AtoB} \cdot {M}_{C} )}{N} \\ {Fct}_{B} = \frac{{M}_{B} \cdot ( {M}_{A} \cdot {M}_{C} - {M}_{AtoC} \cdot {M}_{CtoA} )}{N} \\ {Fct}_{CtoB} = \frac{{M}_{B} \cdot ( {M}_{AtoB} \cdot {M}_{CtoA} - {M}_{A} \cdot {M}_{CtoB} )}{N} \\ {Fct}_{AtoC} = \frac{{M}_{C} \cdot ( {M}_{AtoB} \cdot {M}_{BtoC} - {M}_{AtoC} \cdot {M}_{B} )}{N} \\ {Fct}_{BtoC} = \frac{{M}_{C} \cdot ( {M}_{AtoC} \cdot {M}_{BtoA} - {M}_{A} \cdot {M}_{BtoC} )}{N} \\ {Fct}_{C} = \frac{{M}_{C} \cdot ( {M}_{A} \cdot {M}_{B} - {M}_{AtoB} \cdot {M}_{BtoA} )}{N}\end{matrix}$$
$$and$$
$$N = {M}_{A} \cdot {M}_{B} \cdot {M}_{C} + {M}_{AtoC} \cdot {M}_{BtoA} \cdot {M}_{CtoB} + {M}_{CtoA} \cdot {M}_{AtoB} \cdot {M}_{BtoC} - {M}_{AtoC} \cdot {M}_{B} \cdot {M}_{CtoA} - {M}_{A} \cdot {M}_{BtoC} \cdot {M}_{CtoB} - {M}_{C} \cdot {M}_{AtoB} \cdot {M}_{BtoA} .$$

23. The method according to claim 22, which comprises using the compensation coefficient to determine a compensation voltage value according to the following formula:
$$\{ \begin{matrix}{V}_{A \_ comp} = {Fct}_{A} \cdot {V}_{A \_ meas} + {Fct}_{BtoA} \cdot {V}_{B \_ meas} + {Fct}_{CtoA} \cdot {V}_{C \_ meas} \\ {V}_{B \_ comp} = {Fct}_{AtoB} \cdot {V}_{A \_ meas} + {Fct}_{B} \cdot {V}_{B \_ meas} + {Fct}_{CtoB} \cdot {V}_{C \_ meas} \\ {V}_{C \_ comp} = {Fct}_{AtoC} \cdot {V}_{A \_ meas} + {Fct}_{BtoC} \cdot {V}_{B \_ meas} + {Fct}_{C} \cdot {V}_{C \_ meas}\end{matrix}$$
wherein V_{A_comp} represents the compensation voltage value of phase A, V_{B_comp} represents the compensation voltage value of phase B, V_{C_comp} represents the compensation voltage value of phase C, V_{A_meas} represents a real-time output voltage value of the secondary sides of phase A, V_{B_meas} represents a real-time output voltage value of the secondary sides of phase B, and V_{C_meas} represents a real-time output voltage value of the secondary sides of phase C.

24. A method for electronic mutual inductance, the method comprising:
providing an electronic mutual inductor with three phases each having a Rogowski coil, and using the electronic mutual inductor to convert a current of a primary-side device into a secondary-side voltage;
based on a real-time current of each phase of the primary-side device, generating a real-time output voltage of the corresponding phase;
according to a predetermined compensation coefficient for each phase, compensating for the real-time output voltage on each phase to acquire a corresponding compensation voltage value of each phase, the compensation coefficient being determined based on the coefficients of mutual induction of the Rogowski coils of each phase and the crosstalk induction of each phase to the Rogowski coils of the other phases; and
sending the compensation voltage value to a target device, the compensation voltage value corresponding to an actual current value of the primary-side device.

25. The method according to claim 24, wherein a compensation coefficient matrix D is:
$$D = [ \begin{matrix}{Fct}_{A} & {Fct}_{BtoA} & {Fct}_{CtoA} \\ {Fct}_{AtoB} & {Fct}_{B} & {Fct}_{CtoB} \\ {Fct}_{AtoC} & {Fct}_{BtoC} & {Fct}_{C}\end{matrix} ]$$
$$\{ \begin{matrix}{Fct}_{A} = \frac{{M}_{A} \cdot ( {M}_{B} \cdot {M}_{C} - {M}_{BtoC} \cdot {M}_{CtoB} )}{N} \\ {Fct}_{BtoA} = \frac{{M}_{A} \cdot ( {M}_{BtoC} \cdot {M}_{CtoA} - {M}_{BtoA} \cdot {M}_{C} )}{N} \\ {Fct}_{CtoA} = \frac{{M}_{A} \cdot ( {M}_{BtoA} \cdot {M}_{CtoB} - {M}_{B} \cdot {M}_{CtoA} )}{N} \\ {Fct}_{AtoB} = \frac{{M}_{B} \cdot ( {M}_{AtoC} \cdot {M}_{CtoB} - {M}_{AtoB} \cdot {M}_{C} )}{N} \\ {Fct}_{B} = \frac{{M}_{B} \cdot ( {M}_{A} \cdot {M}_{C} - {M}_{AtoC} \cdot {M}_{CtoA} )}{N} \\ {Fct}_{CtoB} = \frac{{M}_{B} \cdot ( {M}_{AtoB} \cdot {M}_{CtoA} - {M}_{A} \cdot {M}_{CtoB} )}{N} \\ {Fct}_{AtoC} = \frac{{M}_{C} \cdot ( {M}_{AtoB} \cdot {M}_{BtoC} - {M}_{AtoC} \cdot {M}_{B} )}{N} \\ {Fct}_{BtoC} = \frac{{M}_{C} \cdot ( {M}_{AtoC} \cdot {M}_{BtoA} - {M}_{A} \cdot {M}_{BtoC} )}{N} \\ {Fct}_{C} = \frac{{M}_{C} \cdot ( {M}_{A} \cdot {M}_{B} - {M}_{AtoB} \cdot {M}_{BtoA} )}{N}\end{matrix}$$
$$and$$
$$N = {M}_{A} \cdot {M}_{B} \cdot {M}_{C} + {M}_{AtoC} \cdot {M}_{BtoA} \cdot {M}_{CtoB} + {M}_{CtoA} \cdot {M}_{AtoB} \cdot {M}_{BtoC} - {M}_{AtoC} \cdot {M}_{B} \cdot {M}_{CtoA} - {M}_{A} \cdot {M}_{BtoC} \cdot {M}_{CtoB} - {M}_{C} \cdot {M}_{AtoB} \cdot {M}_{BtoA} ;$$
wherein M_{A} represents the coefficient of mutual induction of the Rogowski coil of phase A, M_{AtoB} represents the crosstalk induction of the Rogowski coil of phase A to phase B, M_{AtoC} represents the crosstalk induction of the Rogowski coil of phase A to phase C, I_{A_pri} represents a quantitative current of phase A, f represents the frequency of the quantitative current, V_{A_sec} represents a first voltage on the secondary side of phase A, V_{B_sec} represents a first voltage on the secondary side of phase B, and V_{C_sec} represents a first voltage on the secondary side of phase C;
M_{B} represents the coefficient of mutual induction of the Rogowski coil of phase B, M_{BtoA} represents the crosstalk induction of phase B to the Rogowski coil of phase A, M_{BtoC} represents the crosstalk induction of phase B to the Rogowski coil of phase C, and I_{B_pri} represents a quantitative current of phase B; and
M_{C} represents the coefficient of mutual induction of the Rogowski coil of phase C, M_{CtoA} represents the crosstalk induction of phase C to the Rogowski coil of phase A, M_{CtoB} represents the crosstalk induction of phase C to the Rogowski coil of phase B, and I_{C_pri} represents a quantitative current of phase C.

26. The method according to claim 25, wherein the step of compensating for the real-time output voltage on each phase to acquire the corresponding compensation voltage value of each phase comprises:
$$\{ \begin{matrix}{V}_{A \_ comp} = {Fct}_{A} \cdot {V}_{A \_ meas} + {Fct}_{BtoA} \cdot {V}_{B \_ meas} + {Fct}_{CtoA} \cdot {V}_{C \_ meas} \\ {V}_{B \_ comp} = {Fct}_{AtoB} \cdot {V}_{A \_ meas} + {Fct}_{B} \cdot {V}_{B \_ meas} + {Fct}_{CtoB} \cdot {V}_{C \_ meas} \\ {V}_{C \_ comp} = {Fct}_{AtoC} \cdot {V}_{A \_ meas} + {Fct}_{BtoC} \cdot {V}_{B \_ meas} + {Fct}_{C} \cdot {V}_{C \_ meas}\end{matrix}$$
wherein V_{A_comp} represents the compensation voltage value of phase A, V_{B_comp} represents the compensation voltage value of phase B, V_{C_comp} represents the compensation voltage value of phase C, V_{A_meas} represents a real-time output voltage value of the secondary sides of phase A, V_{B_meas} represents a real-time output voltage value of the secondary sides of phase B, and V_{C_meas} represents a real-time output voltage value of the secondary sides of phase C.

27. An apparatus for an electronic mutual inductor, wherein the electronic mutual inductor is provided with three phases each having a Rogowski coil, and the electronic mutual inductor is configured to convert a current of a primary-side device into a secondary-side voltage, the apparatus comprising:
a first determining unit for determining coefficients of mutual induction of each phase of the Rogowski coil of the electronic mutual inductor and for determining a crosstalk induction of each phase to the Rogowski coils of the respectively other phases;
a first acquisition unit configure to, based on a corresponding coefficient of mutual induction and the crosstalk induction of each phase, acquire a compensation coefficient of the output voltage on the secondary side of that phase, wherein the compensation coefficient is used to compensate for the real-time output voltage value on the secondary side of the electronic mutual inductor to acquire a compensation voltage value, the compensation voltage value corresponding to an actual current value on the primary side.

28. The apparatus according to claim 27, wherein said first determining unit is specifically configured for:
with the three phases of the electronic mutual inductor being phase A, phase B, and phase C, respectively, wherein, when a quantitative current is applied to phase A, and phase B and phase C are kept currentless,
$$\{ \begin{matrix}{M}_{A} = \frac{{V}_{A \_ sec}}{2 π f \cdot {I}_{A \_ pri}} \\ {M}_{AtoB} = \frac{{V}_{B \_ sec}}{2 π f \cdot {I}_{A \_ pri}} \\ {M}_{AtoC} = \frac{{V}_{C \_ sec}}{2 π f \cdot {I}_{A \_ pri}}\end{matrix}$$
wherein M_{A} represents the coefficient of mutual induction of the Rogowski coil of phase A, M_{AtoB} represents the crosstalk induction of the Rogowski coil of phase A to phase B, M_{AtoC} represents the crosstalk induction of the Rogowski coil of phase A to phase C, I_{A_pri} represents a quantitative current of phase A, f represents the frequency of the quantitative current, V_{A_sec} represents a first voltage on the secondary side of phase A, V_{B_sec} represents a first voltage on the secondary side of phase B, and V_{C_sec} represents a first voltage on the secondary side of phase C;
under a condition of applying a quantitative current to phase B and keeping phase A and phase C currentless,
$$\{ \begin{matrix}{M}_{BtoA} = \frac{{V}_{A \_ sec}}{2 π f \cdot {I}_{{B}_{pri}}} \\ {M}_{B} = \frac{{V}_{B \_ sec}}{2 π f \cdot {I}_{{B}_{pri}}} \\ {M}_{BtoC} = \frac{{V}_{C \_ sec}}{2 π f \cdot {I}_{{B}_{pri}}}\end{matrix}$$
wherein M_{B} represents the coefficient of mutual induction of the Rogowski coil of phase B, M_{BtoA} represents the crosstalk induction of phase B to the Rogowski coil of phase A, M_{BtoC} represents the crosstalk induction of phase B to the Rogowski coil of phase C, and I_{B_pri} represents a quantitative current of phase B; and
under a condition of applying a quantitative current to phase C and keeping phase A and phase B currentless,
$$\{ \begin{matrix}{M}_{CtoA} = \frac{{V}_{A \_ sec}}{2 π f \cdot {I}_{C \_ pri}} \\ {M}_{CtoB} = \frac{{V}_{B \_ sec}}{2 π f \cdot {I}_{C \_ pri}} \\ {M}_{C} = \frac{{V}_{C \_ sec}}{2 π f \cdot {I}_{C \_ pri}}\end{matrix}$$
wherein M_{C} represents the coefficient of mutual induction of the Rogowski coil of phase C, M_{CtoA} represents the crosstalk induction of phase C to the Rogowski coil of phase A, M_{CtoB} represents the crosstalk induction of phase C to the Rogowski coil of phase B, and I_{C_pri} represents a quantitative current of phase C.

29. The apparatus according to claim 27, wherein said first acquisition unit is specifically configure to:
determine a compensation coefficient matrix D according to the following formula:
$$D = [ \begin{matrix}{Fct}_{A} & {Fct}_{BtoA} & {Fct}_{CtoA} \\ {Fct}_{AtoB} & {Fct}_{B} & {Fct}_{CtoB} \\ {Fct}_{AtoC} & {Fct}_{BtoC} & {Fct}_{C}\end{matrix} ]$$
$$\{ \begin{matrix}{Fct}_{A} = \frac{{M}_{A} \cdot ( {M}_{B} \cdot {M}_{C} - {M}_{BtoC} \cdot {M}_{CtoB} )}{N} \\ {Fct}_{BtoA} = \frac{{M}_{A} \cdot ( {M}_{BtoC} \cdot {M}_{CtoA} - {M}_{BtoA} \cdot {M}_{C} )}{N} \\ {Fct}_{CtoA} = \frac{{M}_{A} \cdot ( {M}_{BtoA} \cdot {M}_{CtoB} - {M}_{B} \cdot {M}_{CtoA} )}{N} \\ {Fct}_{AtoB} = \frac{{M}_{B} \cdot ( {M}_{AtoC} \cdot {M}_{CtoB} - {M}_{AtoB} \cdot {M}_{C} )}{N} \\ {Fct}_{B} = \frac{{M}_{B} \cdot ( {M}_{A} \cdot {M}_{C} - {M}_{AtoC} \cdot {M}_{CtoA} )}{N} \\ {Fct}_{CtoB} = \frac{{M}_{B} \cdot ( {M}_{AtoB} \cdot {M}_{CtoA} - {M}_{A} \cdot {M}_{CtoB} )}{N} \\ {Fct}_{AtoC} = \frac{{M}_{C} \cdot ( {M}_{AtoB} \cdot {M}_{BtoC} - {M}_{AtoC} \cdot {M}_{B} )}{N} \\ {Fct}_{BtoC} = \frac{{M}_{C} \cdot ( {M}_{AtoC} \cdot {M}_{BtoA} - {M}_{A} \cdot {M}_{BtoC} )}{N} \\ {Fct}_{C} = \frac{{M}_{C} \cdot ( {M}_{A} \cdot {M}_{B} - {M}_{AtoB} \cdot {M}_{BtoA} )}{N}\end{matrix}$$
$$and$$
$$N = {M}_{A} \cdot {M}_{B} \cdot {M}_{C} + {M}_{AtoC} \cdot {M}_{BtoA} \cdot {M}_{CtoB} + {M}_{CtoA} \cdot {M}_{AtoB} \cdot {M}_{BtoC} - {M}_{AtoC} \cdot {M}_{B} \cdot {M}_{CtoA} - {M}_{A} \cdot {M}_{BtoC} \cdot {M}_{CtoB} - {M}_{C} \cdot {M}_{AtoB} \cdot {M}_{BtoA} .$$

30. An apparatus for electronic mutual inductance, wherein an electronic mutual inductor is provided with three phases each having a Rogowski coil, the electronic mutual inductor being configured to convert a current of a primary-side device into a secondary-side voltage, the apparatus comprising:
at least one memory for storing an instruction in non-transitory form; and
at least one processor for executing the method for electronic mutual inductance according to claim 18 by executing the instruction stored in the at least one memory.

31. An electronic mutual inductor, comprising:
three phases each having a Rogowski coil, with the electronic mutual inductor being configured to convert a current of a primary-side device into a secondary-side voltage;
at least one memory for storing an instruction in non-transitory form; and
at least one processor for executing the method for an electronic mutual inductor according to claim 24 by carrying out the instruction stored in the at least one memory.
